(19) United States
(12) Patent Application Publication
(10) Pub. No.: US 2026/0164930 A1
(43) Pub. Date: Jun. 11, 2026

(54) ORGANIC ELECTROLUMINESCENT DEVICES

(71) Applicant: Universal Display Corporation, Ewing, NJ (US)

(72) Inventors: Haridas Mundoor, Ewing, NJ (US); Vinod M. Menon, New York, NY (US); Nicholas J. Thompson, New Hope, PA (US)

(21) Appl. No.: 19/409,059

(22) Filed: Dec. 4, 2025

Related U.S. Application Data
(60) Provisional application No. 63/730,775, filed on Dec. 11, 2024.

(51) Int. Cl. H10K 50/858; G02B 5/00; H10K 50/854; H10K 59/80; H10K 102/00

(52) U.S. Cl. CPC H10K 50/858; G02B 5/008; H10K 59/879; H10K 50/854; H10K 59/877; H10K 2102/331

(57) ABSTRACT

Organic electroluminescent devices are provided, including devices having a unique outcoupling design, wherein the outcoupling layer includes an array of nanoparticles. The array of nanoparticles is arranged in a quasiperiodic array. The quasiperiodic array of nanoparticles allows for more random spacing of the nanoparticles which enhance the device efficiency and allows for tunability of the emission profile by tuning the symmetry of the nanoparticle arrays within the outcoupling layer.

### CROSS-REFERENCE TO RELATED APPLICATIONS

This application claims priority to U.S. Patent Application Ser. No. 63/730,775, filed Dec. 11, 2024, the entire contents of which are incorporated herein by reference.

### FIELD

The present invention relates to emissive devices including organic emissive devices with a plurality of sub-pixels that may be stacked in the same device, and techniques for fabricating the same.

### BACKGROUND

Opto-electronic devices that make use of organic materials are becoming increasingly desirable for a number of reasons. Many of the materials used to make such devices are relatively inexpensive, so organic opto-electronic devices have the potential for cost advantages over inorganic devices. In addition, the inherent properties of organic materials, such as their flexibility, may make them well suited for particular applications such as fabrication on a flexible substrate. Examples of organic opto-electronic devices include organic light emitting diodes/devices (OLEDs), organic phototransistors, organic photovoltaic cells, and organic photodetectors. For OLEDs, the organic materials may have performance advantages over conventional materials. For example, the wavelength at which an organic emissive layer emits light may generally be readily tuned with appropriate dopants.

OLEDs make use of thin organic films that emit light when voltage is applied across the device. OLEDs are becoming an increasingly interesting technology for use in applications such as flat panel displays, illumination, and backlighting. Several OLED materials and configurations are described in U.S. Pat. Nos. 5,844,363, 6,303,238, and 5,707,745, which are incorporated herein by reference in their entirety.

One application for phosphorescent molecules capable of phosphorescent emission is a full color display. Industry standards for such a display call for pixels adapted to emit particular colors, referred to as “saturated” colors. In particular, these standards call for saturated red, green, and blue pixels. Alternatively, the OLED can be designed to emit white light. In conventional liquid crystal displays emission from a white backlight is filtered using absorption filters to produce red, green and blue emission. The same technique can also be used with OLEDs. The white OLED can be either a single EML device or a stack structure. Color may be measured using CIE coordinates, which are well known to the art.

As used herein, the term “organic” includes polymeric materials as well as small molecule organic materials that may be used to fabricate organic opto-electronic devices. “Small molecule” refers to any organic material that is not a polymer, and “small molecules” may actually be quite large. Small molecules may include repeat units in some circumstances. For example, using a long chain alkyl group as a substituent does not remove a molecule from the “small molecule” class. Small molecules may also be incorporated into polymers, for example as a pendent group on a polymer backbone or as a part of the backbone. Small molecules may also serve as the core moiety of a dendrimer, which consists of a series of chemical shells built on the core moiety. The core moiety of a dendrimer may be a fluorescent or phosphorescent small molecule emitter. A dendrimer may be a “small molecule,” and it is believed that all dendrimers currently used in the field of OLEDs are small molecules.

As used herein, “top” means furthest away from the substrate, while “bottom” means closest to the substrate. Where a first layer is described as “disposed over” a second layer, the first layer is disposed further away from substrate. There may be other layers between the first and second layer, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

As used herein, and as would be generally understood by one skilled in the art, a first “Highest Occupied Molecular Orbital” (HOMO) or “Lowest Unoccupied Molecular Orbital” (LUMO) energy level is “greater than” or “higher than” a second HOMO or LUMO energy level if the first energy level is closer to the vacuum energy level. Since ionization potentials (IP) are measured as a negative energy relative to a vacuum level, a higher HOMO energy level corresponds to an IP having a smaller absolute value (an IP that is less negative). Similarly, a higher LUMO energy level corresponds to an electron affinity (EA) having a smaller absolute value (an EA that is less negative). On a conventional energy level diagram, with the vacuum level at the top, the LUMO energy level of a material is higher than the HOMO energy level of the same material. A “higher” HOMO or LUMO energy level appears closer to the top of such a diagram than a “lower” HOMO or LUMO energy level.

As used herein, and as would be generally understood by one skilled in the art, a first work function is “greater than” or “higher than” a second work function if the first work function has a higher absolute value. Because work functions are generally measured as negative numbers relative to vacuum level, this means that a “higher” work function is more negative. On a conventional energy level diagram, with the vacuum level at the top, a “higher” work function is illustrated as further away from the vacuum level in the downward direction. Thus, the definitions of HOMO and LUMO energy levels follow a different convention than work functions.

Layers, materials, regions, and devices may be described herein in reference to the color of light they emit. In general, as used herein, an emissive region that is described as producing a specific color of light may include one or more emissive layers disposed over each other in a stack.

As used herein, a “red” layer, material, region, or device refers to one that emits light in the range of about 580-700 nm or having a highest peak in its emission spectrum in that region. Similarly, a “green” layer, material, region, or device refers to one that emits or has an emission spectrum with a peak wavelength in the range of about 500-600 nm; a “blue” layer, material, or device refers to one that emits or has an emission spectrum with a peak wavelength in the range of about 400-500 nm; a “yellow” layer, material, region, or device refers to one that has an emission spectrum with a peak wavelength in the range of about 540-600 nm; a “cyan” layer, material, or device refers to one that emits or has an emission spectrum with a peak wavelength in the range of about 490-520 nm; and an “orange” layer, material, or device refers to one that emits or has an emission spectrum with a peak wavelength in the range of about 570-620 nm. In some arrangements, separate regions, layers, materials, regions, or devices may provide separate “deep blue” and a “light blue” light. As used herein, in arrangements that provide separate “light blue” and “deep blue”, the “deep blue” component refers to one having a peak emission wavelength that is at least about 4 nm less than the peak emission wavelength of the “light blue” component. Typically, a “light blue” component has a peak emission wavelength in the range of about 465-500 nm, and a “deep blue” or “dark blue” component has a peak emission wavelength in the range of about 400-470 nm, though these ranges may vary for some configurations. A “light green” component has a peak emission wavelength in the range of about 520-560 nm, and a “deep green” or “dark green” component has a peak emission wavelength in the range of about 500-520 nm, though these ranges may vary for some configurations. A near infrared (“NIR”) component has a peak emission wavelength in the range of about 700-1800 nm. Similarly, a color altering layer refers to a layer that converts or modifies another color of light to light having a wavelength as specified for that color. For example, a “red” color filter refers to a filter that results in light having a wavelength in the range of about 580-700 nm. In general, there are two classes of color altering layers: color filters that modify a spectrum by removing unwanted wavelengths of light, and color changing layers that convert photons of higher energy to lower energy. A component “of a color” refers to a component that, when activated or used, produces or otherwise emits light having a particular color as previously described. For example, a “first emissive region of a first color” and a “second emissive region of a second color different than the first color” describes two emissive regions that, when activated within a device, emit two different colors as previously described.

As used herein, emissive materials, layers, and regions may be distinguished from one another and from other structures based upon the spectrum of light initially generated by the material, layer or region, as opposed to light eventually emitted by the same or a different structure. The initial light generation typically is the result of an energy level change resulting in emission of a photon. For example, an organic emissive material may initially generate blue light, which may be converted by a color filter, quantum dot or other structure to red or green light, such that a complete emissive stack or sub-pixel emits the red or green light. In this case the initial emissive material or layer may be referred to as a “blue” component, even though the sub-pixel is a “red” or “green” component.

In some cases, it may be preferable to describe the color of a component such as an emissive region, sub-pixel, color altering layer, or the like, in terms of 1931 CIE coordinates. For example, a yellow emissive material may have multiple peak emission wavelengths, one in or near an edge of the “green” region, and one within or near an edge of the “red” region as previously described. Accordingly, as used herein, each color term also corresponds to a shape in the 1931 CIE coordinate color space. The shape in 1931 CIE color space is constructed by following the locus between two color points and any additional interior points. For example, interior shape parameters for red, green, blue, and yellow may be defined as shown below:

| Color | CIE Shape Parameters |
|---|---|
| Central Red | Locus: [0.6270, 0.3725]; [0.7347, 0.2653]; |
| | Interior: [0.5086, 0.2657] |
| Central Green | Locus: [0.0326, 0.3530]; [0.3731, 0.6245]; |
| | Interior: [0.2268, 0.3321 |
| Central Blue | Locus: [0.1746, 0.0052]; [0.0326, 0.3530]; |
| | Interior: [0.2268, 0.3321] |
| Central Yellow | Locus: [0.373 l, 0.6245]; [0.6270, 0.3725]; |
| | Interior: [0.3700, 0.4087]; [0.2886, 0.4572] |

More details on OLEDs, and the definitions described above, can be found in U.S. Pat. No. 7,279,704, which is incorporated herein by reference in its entirety.

### SUMMARY

According to an embodiment, an organic light emitting diode/device (OLED) is also provided. The OLED can include an anode, a cathode, and an organic layer, disposed between the anode and cathode. According to an embodiment, the organic light emitting device is incorporated into one or more devices selected from a consumer product, an electronic component module, and/or a lighting panel.

An organic emissive device is provided which includes a substrate; a first electrode; an emissive layer comprising including an organic emissive material disposed over the first electrode; an enhancement layer disposed over the emissive layer; and an outcoupling layer disposed over the enhancement layer, wherein the outcoupling layer includes an array of nanoparticles, where the array of nanoparticles is a periodic array or a quasiperiodic array.

The enhancement layer may be a second electrode within the organic emissive device. Alternatively, the device may include a second electrode in addition to the enhancement layer. In an embodiment, the second electrode that is separate from the enhancement layer may be disposed over the emissive layer and may be an optically transparent material, a metal material, or a non-metallic material. In an embodiment, the enhancement layer may be disposed over the second electrode and the bottom surface of the enhancement layer may be in contact with the top surface of the second electrode. In an embodiment, the second electrode may be disposed over the enhancement layer.

The enhancement layer may include a plasmonic material exhibiting surface plasmon resonance that non-radiatively couples to the organic emissive material of the emissive layer and transfers excited state energy from the organic emissive material to non-radiative mode of surface plasmon polaritons. The enhancement layer may be provided no more than a threshold distance away from the organic emissive material. The organic emissive material may have a total non-radiative decay rate constant and a total radiative decay rate constant due to the presence of the enhancement layer. The threshold distance may be a distance where the total non-radiative decay rate constant is equal to the total radiative decay rate constant. The organic emissive material may have a total non-radiative decay constant

$${k}_{non - rad}^{0} ,$$

a total radiative decay constant

$${k}_{rad}^{0} ,$$

a total non-radiative decay rate constant due to the enhancement layer

$${k}_{non - rad}^{plasmon} ,$$

and a total radiative decay rate constant due to the enhancement layer

$${k}_{rad}^{plasmon} .$$

The threshold distance may be a distance at which

$$\frac{{k}_{rad}^{plasmon}}{{k}_{non - rad}^{plasmon}} = \frac{{k}_{rad}^{0}}{{k}_{non - rad}^{0}} .$$

The emission profile for the device may be tuned based upon a selection of an array symmetry of a design of the quasiperiodic array. Each of the arrays of nanoparticles may include a plurality of nanoparticles. The array symmetry may be a rotational symmetry, translation symmetry, and/or the like. A quasiperiodic array may be an array design that has no long-range positional order and where a length scale of the short-range positional periodicity is no greater than a plasmon propagation length of the enhancement layer. In other words, a quasiperiodic array is not a highly ordered array. The interparticle spacing (an edge to edge spacing between adjacent nanoparticles, where the edge are the closest edges between the adjacent nanoparticles) between nanoparticles within the quasiperiodic array may be greater than a largest dimension of a nanoparticle, for example, the interparticle spacing may be at least 200 nm, at least 300 nm, at least 400 nm, at least 500 nm, and/or the like. The lattice periodicity of the quasiperiodic array may be at least 100 nm, at least 200 nm, at least 300 nm, at least 400 nm, more than 500 nm, and/or the like.

The quasiperiodic array may be generated by combining the particle distributions of a first periodic array with a second periodic array, where the first periodic array and the second periodic array have different lattice ordering or periodicities, for example, a square lattice, a hexagonal lattice, an oblique lattice, a rectangular lattice, and/or the like. In the embodiment where a group of nanoparticles forming a square array is arranged in a hexagonal array, the nanoparticles within each grouping of the square array may be an even number, for example, 4, 6, 8, and/or the like. In another embodiment, a group of nanoparticles forming a hexagonal array may be assembled into a square lattice.

The quasiperiodic array may be a higher order array with increased rotational and/or translational symmetries as compared to the array formed by the embedding method. The higher order array may be generated utilizing a mathematical method called a cut and project method where a n-dimensional lattice array is projected into a two-dimensional plane to create a tiling pattern. Nanoparticles may be placed at vertices of the tiling pattern to create the higher order quasiperiodic array. For example, the projections of a 5-dimensional cubic lattice to a two-dimensional plane forms a Penrose tiling pattern and Penrose nanoparticle array with a fivefold rotational symmetry. To increase the order of the array, the dimensionality of the higher dimensional lattices can be increased and then projected into the two-dimensional plane.

The nanoparticle arrays in the outcoupling layer may exhibit a Moiré effect. Such arrays, called Moiré arrays for ease of readability, can be formed by superposing multiple arrays with different lattice symmetries or periodicities by changing the relative lattice orientation with respect to each other. The first periodic array and the second periodic array may be rotated with respect to each other. The degree of rotation may be 5°, 30°, 45°, and/or the like. The degree of rotation may be selected to tune a radiation pattern and emission direction of the device. The quasiperiodic array may also be formed by layering additional periodic arrays with the first periodic array and the second periodic array and stacking them in an out-of-plane direction. Each of these arrays may be separated in the out-of-plane direction by a distance of at least 10 nm, at least 25 nm, at least 50 nm, less than 100 nm, and/or the like. Each of these arrays may be different periodicities as compared to other of the periodic arrays.

The first periodic array and the second periodic array may be placed or arranged within the same plane creating a Moiré array. In the embodiment where the first and second periodic arrays are placed or arranged in the same plane, the nanoparticles may be one of metal nanoparticles and dielectric nanoparticles. The first periodic array and the second periodic array may also be arranged in separate layers with the second periodic array being in a second layer disposed over the first periodic array in a first layer, thereby creating a quasiperiodic array having a Moiré effect. The nanoparticles of the first periodic array layer and the second periodic array layer may be the same type of nanoparticles, for example, both being metal nanoparticles or both being dielectric nanoparticles, or may be different nanoparticle types, for example, the first layer being dielectric nanoparticles and the second layer being metal nanoparticles. If both layers include metal nanoparticles, the outcoupling layer may include a dielectric spacer where the first layer is disposed over the dielectric spacer. The dielectric spacer may have a thickness of less than 20 nm, less than 30 nm, less than 50 nm, less than 100 nm, and or the like, and, preferably, 20 nm±5 nm. A dielectric material may be disposed between the nanoparticles of the first layer to form a planar surface over the nanoparticles. The second layer of nanoparticles may be disposed above the planar surface.

In an embodiment where the first layer includes dielectric nanoparticles, regardless of whether the second layer includes dielectric nanoparticles or metal nanoparticles, the outcoupling layer may include a dielectric spacer layer that has a thickness of less than 2 nm, or may not include a dielectric spacer layer at all. The first layer may be disposed above the dielectric spacer layer or, in the embodiment without a dielectric spacer, on the enhancement layer. The dielectric nanoparticles of the first periodic array may be disposed within a dielectric material, where the dielectric nanoparticles have a refractive index greater than the refractive index of the dielectric material by at least 0.5. The second layer of nanoparticles may be disposed over the first layer of nanoparticles.

The device may be or may be a part of a consumer electronic device, which may be at least one type selected from the group consisting of: a flat panel display, a curved display, a computer monitor, a medical monitor, a television, a billboard, a light for interior or exterior illumination and/or signaling, a heads-up display, a fully or partially transparent display, a flexible display, a rollable display, a foldable display, a stretchable display, a laser printer, a telephone, a cell phone, tablet, a phablet, a personal digital assistant (PDA), a wearable device, a laptop computer, a digital camera, a camcorder, a viewfinder, a micro-display that is less than 2 inches diagonal, a 3-D display, a virtual reality or augmented reality display, a vehicle, an automotive display, a video walls comprising multiple displays tiled together, a theater or stadium screen, and a sign.

### BRIEF DESCRIPTION OF THE DRAWINGS

FIG. 1 shows an organic light emitting device.

FIG. 2 shows an inverted organic light emitting device that does not have a separate electron transport layer.

FIG. 3A-3B show a schematic representation of plasmonic OLEDs. FIG. 3A illustrates a plasmonic OLED where the enhancement layer is a second electrode. FIG. 3B illustrates a plasmonic OLED having a separate enhancement layer and second electrode.

FIG. 4A-4B show simulated modes for plasmonic OLED devices using square arrays of silver nanoparticles for light outcoupling. The numbers in brackets indicate the Miller indices for different lattice modes. FIG. 4A illustrates a simulated surface lattice resonance (SLR) mode. FIG. 4B illustrates a simulated plasmon-mediated surface lattice resonance (PSLR) mode.

FIG. 5A-5F show nanoparticle locations and corresponding geometrical structure factor points for different arrays types. FIG. 5A illustrates the nanoparticle locations for a square array. FIG. 5B illustrates the corresponding geometrical structure factor points for the square array of FIG. 5A. FIG. 5C illustrates the nanoparticle locations for a hexagonal array. FIG. 5D illustrates the corresponding geometrical structure factor points for the hexagonal array of FIG. 5C. FIG. 5E illustrates the nanoparticle locations for a quasiperiodic array formed by combining the square lattice array of FIG. 5A with the hexagonal lattice array of FIG. 5C. FIG. 5F illustrates the corresponding geometrical structure factor points for the quasiperiodic array of FIG. 5E.

FIG. 6A-6C show nanoparticle locations, the corresponding geometrical structure factor points, and a simulated emission profile for a plasmonic OLED having a Penrose-based quasiperiodic array used in the outcoupling layer. FIG. 6A illustrates the nanoparticle locations for the Penrose-based quasiperiodic array. FIG. 6B illustrates the corresponding geometrical structure factor points for the quasiperiodic array of FIG. 6A. FIG. 6C illustrates the simulated emission profile for the quasiperiodic array of FIG. 6A.

FIG. 7A illustrates a simulated EQE plot for Penrose-based quasiperiodic arrays (black) and square arrays (Grey) showing the enhanced light outcoupling of the quasiperiodic array. FIG. 7B illustrates a simulated lattice dispersion for Penrose-based quasiperiodic arrays using a finite difference time domain (FDTD) method.

FIG. 8A-8F show example quasiperiodic high symmetry arrays from a tiling pattern and corresponding structure factor pattern for the arrays. FIG. 8A illustrates the quasiperiodic high symmetry array from a tiling pattern where n=7. FIG. 8D illustrates the corresponding structure factor pattern for the array of FIG. 8A. FIG. 8B illustrates the quasiperiodic high symmetry array from a tiling pattern where n=9. FIG. 8E illustrates the corresponding structure factor pattern for the array of FIG. 8B. FIG. 8C illustrates the quasiperiodic high symmetry array from a tiling pattern where n=13. FIG. 8F illustrates the corresponding structure factor pattern for the array of FIG. 8C.

FIG. 9A-9C show nanoparticle locations and arrangements in Moiré patterns formed by superposition of two square arrays with one of the arrays being rotated with respect to each other. FIG. 9A illustrates a Moiré pattern formed by superposition of two square arrays with one of the arrays being rotated by 5° with respect to each other. FIG. 9B illustrates a Moiré pattern formed by superposition of two square arrays with one of the arrays being rotated by 30° with respect to each other. FIG. 9C illustrates a Moiré pattern formed by superposition of two square arrays with one of the arrays being rotated by 45° with respect to each other.

FIG. 10A-10E show schematic representations of plasmonic OLEDs utilizing arrays exhibiting a Moiré effect. FIG. 10A illustrates a plasmonic OLED exhibiting a Moiré effect formed by a periodic array of recessions on a second electrode and a metal nanoparticle periodic array. FIG. 10B illustrates a plasmonic OLED exhibiting a Moiré effect formed by a dielectric nanoparticle periodic array on a second electrode and a metal nanoparticle array deposited above the dielectric nanoparticle array. FIG. 10C illustrates a plasmonic OLED exhibiting a Moiré effect formed by stacked layers of metal nanoparticle periodic arrays. FIG. 10D illustrates a plasmonic OLED exhibiting a Moiré effect formed by a periodic array of dielectric nanoparticles disposed in another dielectric medium deposited on an enhancement layer and a second layer of a periodic array of dielectric nanoparticles above the first layer. FIG. 10E illustrates a plasmonic OLED exhibiting a Moiré effect formed by a periodic array of metal nanoparticles in a dielectric layer deposited on the enhancement layer and a periodic array of dielectric nanoparticles above the first layer.

FIG. 11A-11C show nanoparticle locations and arrangements. FIG. 11A illustrates a hexagonal array. FIG. 11B shows a chirped array showing variations in lattice periodicity. FIG. 11C shows a chirped array showing variations in array symmetry from hexagonal to rectangular.

FIGS. 12A and 12B show three-dimensional nanoparticle locations and arrangements. FIG. 12A illustrates three-dimensional metal nanoparticles. FIG. 12B illustrates three-dimensional dielectric nanoparticles.

### DETAILED DESCRIPTION

Generally, an OLED comprises at least one organic layer disposed between and electrically connected to an anode and a cathode. When a current is applied, the anode injects holes and the cathode injects electrons into the organic layer(s). The injected holes and electrons each migrate toward the oppositely charged electrode. When an electron and hole localize on the same molecule, an “exciton,” which is a localized electron-hole pair having an excited energy state, is formed. Light is emitted when the exciton relaxes via a photoemissive mechanism. In some cases, the exciton may be localized on an excimer or an exciplex. Non-radiative mechanisms, such as thermal relaxation, may also occur, but are generally considered undesirable.

The initial OLEDs used emissive molecules that emitted light from their singlet states (“fluorescence”) as disclosed, for example, in U.S. Pat. No. 4,769,292, which is incorporated by reference in its entirety. Fluorescent emission generally occurs in a time frame of less than 10 nanoseconds.

More recently, OLEDs having emissive materials that emit light from triplet states (“phosphorescence”) have been demonstrated. Baldo et al., “Highly Efficient Phosphorescent Emission from Organic Electroluminescent Devices,” Nature, vol. 395, 151-154, 1998; (“Baldo-I”) and Baldo et al., “Very high-efficiency green organic light-emitting devices based on electrophosphorescence,” Appl. Phys. Lett., vol. 75, No. 3, 4-6 (1999) (“Baldo-II”), are incorporated by reference in their entireties. Phosphorescence is described in more detail in U.S. Pat. No. 7,279,704 at cols. 5-6, which are incorporated by reference.

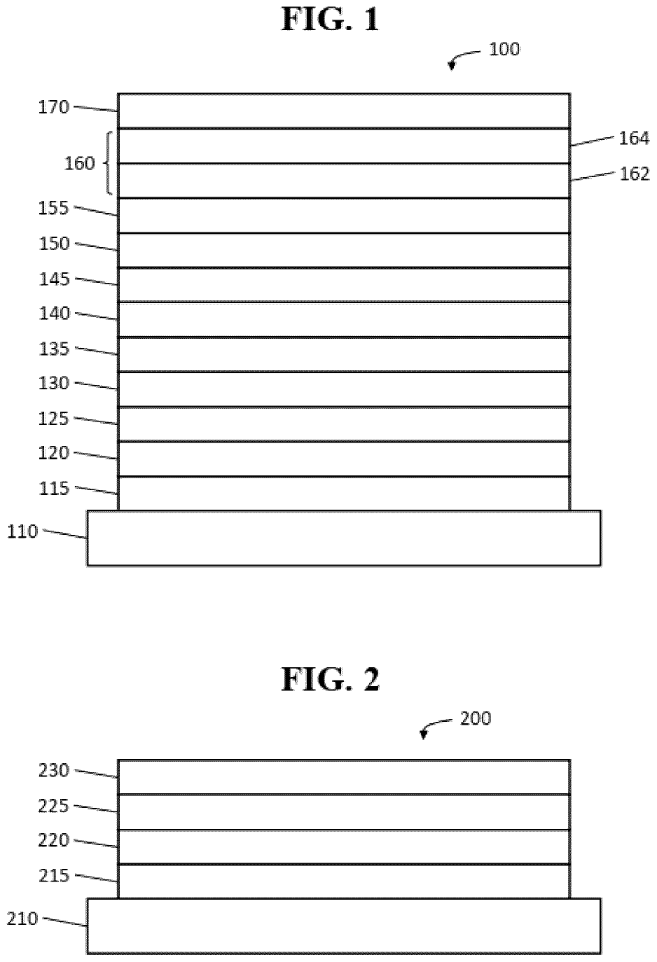

FIG. 1 shows an organic light emitting device 100. The figures are not necessarily drawn to scale. Device 100 may include a substrate 110, an anode 115, a hole injection layer 120, a hole transport layer 125, an electron blocking layer 130, an emissive layer 135, a hole blocking layer 140, an electron transport layer 145, an electron injection layer 150, a protective layer 155, a cathode 160, and a barrier layer 170. Cathode 160 is a compound cathode having a first conductive layer 162 and a second conductive layer 164. Device 100 may be fabricated by depositing the layers described, in order. The properties and functions of these various layers, as well as example materials, are described in more detail in U.S. Pat. No. 7,279,704 at cols. 6-10, which are incorporated by reference.

More examples for each of these layers are available. For example, a flexible and transparent substrate-anode combination is disclosed in U.S. Pat. No. 5,844,363, which is incorporated by reference in its entirety. An example of a p-doped hole transport layer is m-MTDATA doped with F₄-TCNQ at a molar ratio of 50:1, as disclosed in U.S. Patent Application Publication No. 2003/0230980, which is incorporated by reference in its entirety. Examples of emissive and host materials are disclosed in U.S. Pat. No. 6,303,238 to Thompson et al., which is incorporated by reference in its entirety. An example of an n-doped electron transport layer is BPhen doped with Li at a molar ratio of 1:1, as disclosed in U.S. Patent Application Publication No. 2003/0230980, which is incorporated by reference in its entirety. U.S. Pat. Nos. 5,703,436 and 5,707,745, which are incorporated by reference in their entireties, disclose examples of cathodes including compound cathodes having a thin layer of metal such as Mg:Ag with an overlying transparent, electrically-conductive, sputter-deposited ITO layer. The theory and use of blocking layers is described in more detail in U.S. Pat. No. 6,097,147 and U.S. Patent Application Publication No. 2003/0230980, which are incorporated by reference in their entireties. Examples of injection layers are provided in U.S. Patent Application Publication No. 2004/0174116, which is incorporated by reference in its entirety. Barrier layer 170 may be a single- or multi-layer barrier and may cover or surround the other layers of the device. The barrier layer 170 may also surround the substrate 110, and/or it may be arranged between the substrate and the other layers of the device. The barrier also may be referred to as an encapsulant, encapsulation layer, protective layer, or permeation barrier, and typically provides protection against permeation by moisture, ambient air, and other similar materials through to the other layers of the device. Examples of barrier layer materials and structures are provided in U.S. Pat. Nos. 6,537,688, 6,597,111, 6,664,137, 6,835,950, 6,888,305, 6,888,307, 6,897,474, 7,187,119, and 7,683,534, each of which is incorporated by reference in its entirety.

FIG. 2 shows an inverted OLED 200. The device includes a substrate 210, a cathode 215, an emissive layer 220, a hole transport layer 225, and an anode 230. Device 200 may be fabricated by depositing the layers described, in order. Because the most common OLED configuration has a cathode disposed over the anode, and device 200 has cathode 215 disposed under anode 230, device 200 may be referred to as an “inverted” OLED. Materials similar to those described with respect to device 100 may be used in the corresponding layers of device 200. FIG. 2 provides one example of how some layers may be omitted from the structure of device 100.

The simple layered structure illustrated in FIGS. 1 and 2 is provided by way of non-limiting example, and it is understood that embodiments of the invention may be used in connection with a wide variety of other structures. The specific materials and structures described are exemplary in nature, and other materials and structures may be used. Functional OLEDs may be achieved by combining the various layers described in different ways, or layers may be omitted entirely, based on design, performance, and cost factors. Other layers not specifically described may also be included. Materials other than those specifically described may be used. Although many of the examples provided herein describe various layers as comprising a single material, it is understood that combinations of materials, such as a mixture of host and dopant, or more generally a mixture, may be used. Also, the layers may have various sublayers. The names given to the various layers herein are not intended to be strictly limiting. For example, in device 200, hole transport layer 225 transports holes and injects holes into emissive layer 220, and may be described as a hole transport layer or a hole injection layer. In one embodiment, an OLED may be described as having an “organic layer” disposed between a cathode and an anode. This organic layer may comprise a single layer, or may further comprise multiple layers of different organic materials as described, for example, with respect to FIGS. 1 and 2.

Structures and materials not specifically described may also be used, such as OLEDs comprised of polymeric materials (PLEDs) such as disclosed in U.S. Pat. No. 5,247,190 to Friend et al., which is incorporated by reference in its entirety. By way of further example, OLEDs having a single organic layer may be used. OLEDs may be stacked, for example as described in U.S. Pat. No. 5,707,745 to Forrest et al, which is incorporated by reference in its entirety. The OLED structure may deviate from the simple layered structure illustrated in FIGS. 1 and 2. For example, the substrate may include an angled reflective surface to improve out-coupling, such as a mesa structure as described in U.S. Pat. No. 6,091,195 to Forrest et al., and/or a pit structure as described in U.S. Pat. No. 5,834,893 to Bulovic et al., which are incorporated by reference in their entireties.

In some embodiments disclosed herein, emissive layers or materials, such as emissive layer 135 and emissive layer 220 shown in FIGS. 1-2, respectively, may include quantum dots. The emissive layer may use different emissive display technologies. Such technologies may include inorganic and/or organic devices, such as LEDs, mini LEDs, microLEDs, thin electroluminescent films, organic light emitting devices, and the like. An “emissive layer” or “emissive material” as disclosed herein may include an organic emissive material and/or an emissive material that contains quantum dots or equivalent structures, unless indicated to the contrary explicitly or by context according to the understanding of one of skill in the art. In general, an emissive layer includes emissive material within a host matrix. Such an emissive layer may include only a quantum dot material which converts light emitted by a separate emissive material or other emitter, or it may also include the separate emissive material or other emitter, or it may emit light itself directly from the application of an electric current. Similarly, a color altering layer, color filter, upconversion, or downconversion layer or structure may include a material containing quantum dots, though such layer may not be considered an “emissive layer” as disclosed herein. In general, an “emissive layer” or material is one that emits an initial light based on an injected electrical charge, where the initial light may be altered by another layer such as a color filter or other color altering layer that does not itself emit an initial light within the device, but may re-emit altered light of a different spectra content based upon absorption of the initial light emitted by the emissive layer and downconversion to a lower energy light emission. In some embodiments disclosed herein, the color altering layer, color filter, upconversion, and/or downconversion layer may be disposed outside of an OLED device, such as above or below an electrode of the OLED device.

Unless otherwise specified, any of the layers of the various embodiments may be placed, disposed, or deposited by any suitable method. For the organic layers, preferred methods include thermal evaporation, ink-jet, such as described in U.S. Pat. Nos. 6,013,982 and 6,087,196, which are incorporated by reference in their entireties, organic vapor phase deposition (OVPD), such as described in U.S. Pat. No. 6,337,102 to Forrest et al., which is incorporated by reference in its entirety, and deposition by organic vapor jet printing (OVJP), such as described in U.S. Pat. No. 7,431,968, which is incorporated by reference in its entirety. Other suitable deposition methods include spin coating and other solution-based processes. Solution based processes are preferably carried out in nitrogen or an inert atmosphere. For the other layers, preferred methods include thermal evaporation. Preferred patterning methods include deposition through a mask, cold welding such as described in U.S. Pat. Nos. 6,294,398 and 6,468,819, which are incorporated by reference in their entireties, and patterning associated with some of the deposition methods such as ink-jet and OVJD. Other methods may also be used. The materials to be deposited may be modified to make them compatible with a particular deposition method. For example, substituents such as alkyl and aryl groups, branched or unbranched, and preferably containing at least 3 carbons, may be used in small molecules to enhance their ability to undergo solution processing. Substituents having 20 carbons or more may be used, and 3-20 carbons is a preferred range. Materials with asymmetric structures may have better solution processibility than those having symmetric structures, because asymmetric materials may have a lower tendency to recrystallize. Dendrimer substituents may be used to enhance the ability of small molecules to undergo solution processing.

Devices fabricated in accordance with embodiments of the present invention may further optionally comprise a barrier layer. One purpose of the barrier layer is to protect the electrodes and organic layers from damaging exposure to harmful species in the environment including moisture, vapor and/or gases, etc. The barrier layer may be deposited over, under or next to a substrate, an electrode, or over any other parts of a device including an edge. The barrier layer may comprise a single layer, or multiple layers. The barrier layer may be formed by various known chemical vapor deposition techniques and may include compositions having a single phase as well as compositions having multiple phases. Any suitable material or combination of materials may be used for the barrier layer. The barrier layer may incorporate an inorganic or an organic compound or both. The preferred barrier layer comprises a mixture of a polymeric material and a non-polymeric material as described in U.S. Pat. No. 7,968,146, PCT Pat. Application Nos. PCT/US2007/023098 and PCT/US2009/042829, which are herein incorporated by reference in their entireties. To be considered a “mixture”, the aforesaid polymeric and non-polymeric materials comprising the barrier layer should be deposited under the same reaction conditions and/or at the same time. The weight ratio of polymeric to non-polymeric material may be in the range of 95:5 to 5:95. The polymeric material and the non-polymeric material may be created from the same precursor material. In one example, the mixture of a polymeric material and a non-polymeric material consists essentially of polymeric silicon and inorganic silicon.

In some embodiments, at least one of the anode, the cathode, or a new layer disposed over the organic emissive layer functions as an enhancement layer. The enhancement layer comprises a plasmonic material exhibiting surface plasmon resonance that non-radiatively couples to the emitter material and transfers excited state energy from the emitter material to non-radiative mode of surface plasmon polariton. The enhancement layer is provided no more than a threshold distance away from the organic emissive layer, where the emitter material has a total non-radiative decay rate constant and a total radiative decay rate constant due to the presence of the enhancement layer and the threshold distance is where the total non-radiative decay rate constant is equal to the total radiative decay rate constant. In some embodiments, the OLED further comprises an outcoupling layer. In some embodiments, the outcoupling layer is disposed over the enhancement layer on the opposite side of the organic emissive layer. In some embodiments, the outcoupling layer is disposed on opposite side of the emissive layer from the enhancement layer but still outcouples energy from the surface plasmon mode of the enhancement layer. The outcoupling layer scatters or extracts the energy from the surface plasmon polaritons. In some embodiments this energy is scattered or extracted as photons to free space. In other embodiments, the energy is scattered or extracted from the surface plasmon mode into other modes of the device such as but not limited to the organic waveguide mode, the substrate mode, or another waveguiding mode. If energy is scattered or extracted to the non-free space mode of the OLED other outcoupling schemes could be incorporated to extract that energy to free space. In some embodiments, one or more dielectric spacer layers can be disposed between the enhancement layer and the outcoupling layer. The plasmonic stack may include a dielectric spacer material (i.e., a dielectric spacer layer) having a refractive index selected based on a color of light emitted by the organic emissive material. In an embodiment, the dielectric spacer material (i.e., dielectric spacer layer) may be located between the enhancement layer and the nanoparticles in the plasmonic stack. In an alternative embodiment, the dielectric spacer material may be located between the two electrodes in the plasmonic stack. In yet another embodiment, the dielectric spacer material may be located on either side of, but not necessarily adjacent to, either electrode, outside of the plasmonic stack. In yet another embodiment, the dielectric spacer material may be located between the enhancement layer and the outcoupling layer or may be integrated within the outcoupling layer. In some embodiments, the dielectric spacer layer may be found only in a plasmonic stack sub-pixel, only in a non-plasmonic stack sub-pixel or in both. Examples of material suitable for use in dielectric spacer layers include dielectric materials, including organic, inorganic, perovskites, oxides, and may include stacks and/or mixtures of these materials.

The enhancement layer modifies the effective properties of the medium in which the emitter material resides resulting in any or all of the following: a decreased rate of emission, a modification of emission line-shape, a change in emission intensity with angle, a change in the stability of the emitter material, a change in the efficiency of the OLED, and reduced efficiency roll-off of the OLED device. Placement of the enhancement layer on the cathode side, anode side, or on both sides results in OLED devices which take advantage of any of the above-mentioned effects. In addition to the specific functional layers mentioned herein and illustrated in the various OLED examples shown in the figures, the OLEDs according to the present disclosure may include any of the other functional layers often found in OLEDs.

The enhancement layer can be comprised of plasmonic materials, optically active metamaterials, or hyperbolic metamaterials. As used herein, a plasmonic material is a material in which the real part of the dielectric constant crosses zero in the visible or ultraviolet region of the electromagnetic spectrum. In some embodiments, the plasmonic material includes at least one metal. In such embodiments the metal may include at least one of Ag, Al, Au, Ir, Pt, Ni, Cu, W, Ta, Fe, Cr, Mg, Ga, Rh, Ti, Ru, Pd, In, Bi, Ca alloys or mixtures of these materials, and stacks of these materials. In general, a metamaterial is a medium composed of different materials where the medium as a whole acts differently than the sum of its material parts. In particular, we define optically active metamaterials as materials which have both negative permittivity and negative permeability. Hyperbolic metamaterials, on the other hand, are anisotropic media in which the permittivity or permeability are of different sign for different spatial directions. Optically active metamaterials and hyperbolic metamaterials are strictly distinguished from many other photonic structures such as Distributed Bragg Reflectors (“DBRs”) in that the medium should appear uniform in the direction of propagation on the length scale of the wavelength of light. Using terminology that one skilled in the art can understand: the dielectric constant of the metamaterials in the direction of propagation can be described with the effective medium approximation. Plasmonic materials and metamaterials provide methods for controlling the propagation of light that can enhance OLED performance in a number of ways.

In some embodiments, the enhancement layer is provided as a planar layer. In other embodiments, the enhancement layer has wavelength-sized features that are arranged periodically, quasi-periodically, or randomly, or sub-wavelength-sized features that are arranged periodically, quasi-periodically, or randomly. In some embodiments, the wavelength-sized features and the sub-wavelength-sized features have sharp edges.

In some embodiments, the outcoupling layer has wavelength-sized features that are arranged periodically, quasi-periodically, or randomly, or sub-wavelength-sized features that are arranged periodically, quasi-periodically, or randomly. In some embodiments, the outcoupling layer may be composed of a plurality of nanoparticles and in other embodiments the outcoupling layer is composed of a plurality of nanoparticles disposed over a material. In these embodiments the outcoupling may be tunable by at least one of varying a size of the plurality of nanoparticles, varying a shape of the plurality of nanoparticles, changing a material of the plurality of nanoparticles, adjusting a thickness of the material, changing the refractive index of the material or an additional layer disposed on the plurality of nanoparticles, varying a thickness of the enhancement layer, and/or varying the material of the enhancement layer. The plurality of nanoparticles of the device may be formed from at least one of metal, dielectric material, semiconductor materials, an alloy of metal, a mixture of dielectric materials, a stack or layering of one or more materials, and/or a core of one type of material and that is coated with a shell of a different type of material. In some embodiments, the outcoupling layer is composed of at least metal nanoparticles where the metal is selected from the group consisting of Ag, Al, Au, Ir, Pt, Ni, Cu, W, Ta, Fe, Cr, Mg, Ga, Rh, Ti, Ru, Pd, In, Bi, Ca, alloys or mixtures of these materials, and stacks of these materials. The plurality of nanoparticles may have additional layer disposed over them. In some embodiments, the polarization of the emission can be tuned using the outcoupling layer. Varying the dimensionality and periodicity of the outcoupling layer can select a type of polarization that is preferentially outcoupled to air. In some embodiments the outcoupling layer also acts as an electrode of the device.

In embodiments of the disclosed subject matter, a device may include an enhancement layer that is disposed over an emissive area of at least one sub-pixel that is configured to have a Lambertian emission and/or at least one sub-pixel having a microcavity configured for direct emission, as described in detail below. In at least some of such embodiments, the enhancement layer may include a plasmonic structure that is disposed a predetermined threshold distance from the emissive area. The predetermined threshold distance may be a distance at which a total non-radiative decay rate constant is equal to a total radiative decay rate constant. In some of such embodiments, device may include an outcoupling layer is disposed over the enhancement layer on the opposite side of the emissive area.

It is believed that the internal quantum efficiency (IQE) of fluorescent OLEDs can exceed the 25% spin statistics limit through delayed fluorescence. As used herein, there are two types of delayed fluorescence, i.e., P-type delayed fluorescence and E-type delayed fluorescence. P-type delayed fluorescence is generated from triplet-triplet annihilation (TTA).

In some embodiments, a compound in an emissive material and/or layer in an OLED may be used as a phosphorescent sensitizer, where one or multiple layers in the OLED may include an acceptor in the form of one or more fluorescent and/or delayed fluorescence emitters. In some embodiments, the compound can be used as one component of an exciplex to be used as a sensitizer. As a phosphorescent sensitizer, the compound may be capable of energy transfer to the acceptor, and the acceptor may emit the energy or further transfer energy to a final emitter. The acceptor concentrations may range from 0.001% to 100%. The acceptor may be in either the same layer as the phosphorescent sensitizer or in one or more different layers. In some embodiments, the acceptor may be a TADF emitter. In some embodiments, the acceptor may be a fluorescent emitter. In some embodiments, the emission may arise from any or all of the sensitizer, acceptor, and/or final emitter.

On the other hand, E-type delayed fluorescence described above does not rely on the collision of two triplets, but rather on the thermal population between the triplet states and the singlet excited states. Compounds that are capable of generating E-type delayed fluorescence are required to have very small singlet-triplet gaps. Thermal energy can activate the transition from the triplet state back to the singlet state. This type of delayed fluorescence is also known as thermally activated delayed fluorescence (TADF). A distinctive feature of TADF is that the delayed component increases as temperature rises due to the increased thermal energy. If the reverse intersystem crossing rate is fast enough to minimize the non-radiative decay from the triplet state, the fraction of back populated singlet excited states can potentially reach 75%. The total singlet fraction can be 100%, far exceeding the spin statistics limit for electrically generated excitons.

E-type delayed fluorescence characteristics can be found in an exciplex system or in a single compound. Without being bound by theory, it is believed that E-type delayed fluorescence requires the luminescent material to have a small singlet-triplet energy gap (AES-T). Organic, non-metal containing, donor-acceptor luminescent materials may be able to achieve this. The emission in these materials is often characterized as a donor-acceptor charge-transfer (CT) type emission. The spatial separation of the HOMO and LUMO in these donor-acceptor type compounds often results in small AES-T. These states may involve CT states. Often, donor-acceptor luminescent materials are constructed by connecting an electron donor moiety such as amino- or carbazole-derivatives and an electron acceptor moiety such as N-containing six-membered aromatic ring.

Devices fabricated in accordance with embodiments of the invention can be incorporated into a wide variety of electronic component modules (or units) that can be incorporated into a variety of electronic products or intermediate components. Examples of such electronic products or intermediate components include display screens, lighting devices such as discrete light source devices or lighting panels, etc. that can be utilized by the end-user product manufacturers. Such electronic component modules can optionally include the driving electronics and/or power source(s). Devices fabricated in accordance with embodiments of the invention can be incorporated into a wide variety of consumer products that have one or more of the electronic component modules (or units) incorporated therein. A consumer product comprising an OLED that includes the compound of the present disclosure in the organic layer in the OLED is disclosed. Such consumer products would include any kind of products that include one or more light source(s) and/or one or more of some type of visual displays. Some examples of such consumer products include a flat panel display, a curved display, a computer monitor, a medical monitor, a television, a billboard, a light for interior or exterior illumination and/or signaling, a heads-up display, a fully or partially transparent display, a flexible display, a rollable display, a foldable display, a stretchable display, a laser printer, a telephone, a cell phone, tablet, a phablet, a personal digital assistant (PDA), a wearable device, a laptop computer, a digital camera, a camcorder, a viewfinder, a micro-display that is less than 2 inches diagonal, a 3-D display, a virtual reality or augmented reality display, a vehicle, an automotive display, a video walls comprising multiple displays tiled together, a theater or stadium screen, an optical communication device, and a sign. Various control mechanisms may be used to control devices fabricated in accordance with the present invention, including passive matrix and active matrix. Many of the devices are intended for use in a temperature range comfortable to humans, such as 18 C to 30 C, and more preferably at room temperature (20-25 C), but could be used outside this temperature range, for example, from −40 C to 80 C.

The materials and structures described herein may have applications in devices other than OLEDs. For example, other optoelectronic devices such as organic solar cells and organic photodetectors may employ the materials and structures. More generally, organic devices, such as organic transistors, may employ the materials and structures.

In some embodiments, the OLED has one or more characteristics selected from the group consisting of being flexible, being rollable, being foldable, being stretchable, and being curved. In some embodiments, the OLED is transparent or semi-transparent. In some embodiments, the OLED further comprises a layer having carbon nanotubes.

In some embodiments, the OLED further comprises a layer having a delayed fluorescent emitter. In some embodiments, the OLED comprises a RGB pixel arrangement or white plus color filter pixel arrangement. In some embodiments, the OLED is a mobile device, a hand-held device, or a wearable device. In some embodiments, the OLED is a display panel having less than 10-inch diagonal or 50 square inch area. In some embodiments, the OLED is a display panel having at least 10-inch diagonal or 50 square inch area. In some embodiments, the OLED is a lighting panel.

In some embodiments of the emissive region, the emissive region further comprises a host.

In some embodiments, the compound causing light to be generated can be an emissive dopant. In some embodiments, the compound can produce emissions via phosphorescence, fluorescence, thermally activated delayed fluorescence, i.e., TADF (also referred to as E-type delayed fluorescence), triplet-triplet annihilation, or combinations of these processes, including phosphor sensitized fluorescence.

The OLED disclosed herein can be incorporated into one or more of a consumer product, an electronic component module, and a lighting panel. The organic layer can be an emissive layer and the compound can be an emissive dopant in some embodiments, while the compound can be a non-emissive dopant in other embodiments.

The organic layer can also include a host. In some embodiments, two or more hosts are preferred. In some embodiments, the hosts used may be a) bipolar, b) electron transporting, c) hole transporting or d) wide band gap materials that play little role in charge transport. In some embodiments, the host can include a metal complex. The host can be an inorganic compound.

### Combination with Other Materials

The materials described herein as useful for a particular layer in an organic light emitting device may be used in combination with a wide variety of other materials present in the device. For example, emissive dopants disclosed herein may be used in conjunction with a wide variety of hosts, transport layers, blocking layers, injection layers, electrodes and other layers that may be present. The materials described or referred to below are non-limiting examples of materials that may be useful in combination with the compounds disclosed herein, and one of skill in the art can readily consult the literature to identify other materials that may be useful in combination.

Various materials may be used for the various emissive and non-emissive layers and arrangements disclosed herein. Examples of suitable materials are disclosed in U.S. Patent Application Publication No. 2017/0229663, which is incorporated by reference in its entirety.

### Conductivity Dopants:

A charge transport layer can be doped with conductivity dopants to substantially alter its density of charge carriers, which will in turn alter its conductivity. The conductivity is increased by generating charge carriers in the matrix material, and depending on the type of dopant, a change in the Fermi level of the semiconductor may also be achieved. Hole-transporting layer can be doped by p-type conductivity dopants and n-type conductivity dopants are used in the electron-transporting layer.

### HIL/HTL:

A hole injecting/transporting material to be used in the present invention is not particularly limited, and any compound may be used as long as the compound is typically used as a hole injecting/transporting material.

### EBL:

An electron blocking layer (EBL) may be used to reduce the number of electrons and/or excitons that leave the emissive layer. The presence of such a blocking layer in a device may result in substantially higher efficiencies, and or longer lifetime, as compared to a similar device lacking a blocking layer. Also, a blocking layer may be used to confine emission to a desired region of an OLED. In some embodiments, the EBL material has a higher LUMO (closer to the vacuum level) and/or higher triplet energy than the emitter closest to the EBL interface. In some embodiments, the EBL material has a higher LUMO (closer to the vacuum level) and or higher triplet energy than one or more of the hosts closest to the EBL interface. In one aspect, the compound used in EBL contains the same molecule or the same functional groups used as one of the hosts described below.

### Host:

The light emitting layer of the organic EL device of the present invention preferably contains at least a metal complex as light emitting material, and may contain a host material using the metal complex as a dopant material. Examples of the host material are not particularly limited, and any metal complexes or organic compounds may be used as long as the triplet energy of the host is larger than that of the dopant. Any host material may be used with any dopant so long as the triplet criteria is satisfied.

### HBL:

A hole blocking layer (HBL) may be used to reduce the number of holes and/or excitons that leave the emissive layer. The presence of such a blocking layer in a device may result in substantially higher efficiencies and/or longer lifetime as compared to a similar device lacking a blocking layer. Also, a blocking layer may be used to confine emission to a desired region of an OLED. In some embodiments, the HBL material has a lower HOMO (further from the vacuum level) and or higher triplet energy than the emitter closest to the HBL interface. In some embodiments, the HBL material has a lower HOMO (further from the vacuum level) and or higher triplet energy than one or more of the hosts closest to the HBL interface.

### ETL:

An electron transport layer (ETL) may include a material capable of transporting electrons. The electron transport layer may be intrinsic (undoped), or doped. Doping may be used to enhance conductivity. Examples of the ETL material are not particularly limited, and any metal complexes or organic compounds may be used as long as they are typically used to transport electrons.

### Charge Generation Layer (CGL)

In tandem or stacked OLEDs, the CGL plays an essential role in the performance, which is composed of an n-doped layer and a p-doped layer for injection of electrons and holes, respectively. Electrons and holes are supplied from the CGL and electrodes. The consumed electrons and holes in the CGL are refilled by the electrons and holes injected from the cathode and anode, respectively; then, the bipolar currents reach a steady state gradually. Typical CGL materials include n and p conductivity dopants used in the transport layers.

In plasmonic OLEDs, the nanoparticles in the outcoupling layer control not only the light outcoupling efficiency, but also the emission profile of the device. For randomly ordered arrays of nanoparticles in the outcoupling layer, the light outcoupling efficiency increases with particle fill fraction until the average edge-to-edge spacing between two adjacent particles is comparable to the particle size. Further increase in the particle density will lead to reduced light outcoupling efficiency due to the increased optical losses associated with the interparticle coupling between nearby particles. The emission profile is more Lambertian-like for devices using random particle arrays for light outcoupling. Further enhancement in device efficiency and the emission profile can be achieved by tuning the particle arrangement in the outcoupling layer. The described device includes nanoparticle array designs that achieved enhanced device efficiency and a tunable emission profile by tuning the symmetry of the nanoparticle arrays in the outcoupling layer.

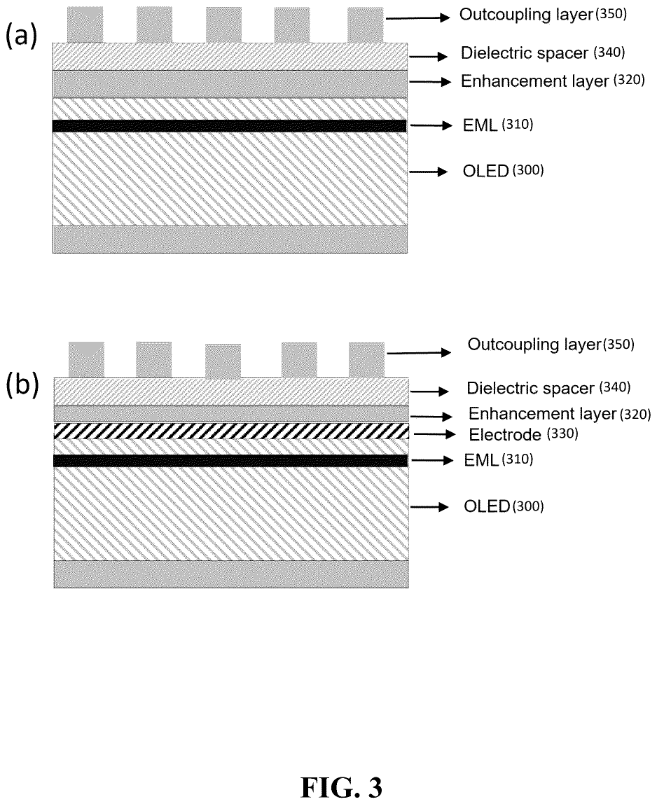

The described device includes a substrate, a first electrode, an emissive layer disposed over the first electrode, an enhancement layer disposed over the emissive layer, and an outcoupling layer disposed over the enhancement layer. The device could include different variations of layers, for example, additional layers, the layers in a different order, and/or the like. Such stacks are described in connection with FIG. 1 and FIG. 2. For example, the plasmonic OLED could be “flipped”, similar to the FIG. 2 arrangement, where the nanoparticle layer is closer to the substrate. The described device includes a unique outcoupling layer where the nanoparticles of the outcoupling layer form a quasiperiodic array. These arrays can provide significant enhancement in light outcoupling efficiency and also provide tunability of the emission profile of the device. In some embodiments, these arrays can reduce angle dependent emission color shift. FIG. 3 shows a schematic representation of a plasmonic OLED, illustrating the organic layer 300, emissive layer (EML) 310, enhancement layer 320, and the outcoupling layer 350. In some embodiments, and as illustrated in FIG. 3a, the metallic cathode, or second electrode, is the enhancement layer 320 for the plasmonic OLEDs. The thickness of the enhancement layer 320 in such an embodiment may be less than 20 nm, less than 30 nm, less than 50 nm, less than 75 nm, and/or the like, or preferably 40 nm±5 nm. The enhancement layer 320, which serves as the second electrode, may be made of a metallic material, for example, gold, silver, aluminum, platinum, rhodium, and/or the like.

In some embodiments, and as illustrated in FIG. 3b, the second electrode 330 may be deposited above the emissive layer 310. When an electrode layer 330 that is separate from the enhancement layer 320 is utilized, the electrode 330 may be deposited above the organic (emissive) layer 310 and the enhancement layer 320 may be disposed over the second electrode 330. In some embodiments, the bottom surface of the enhancement layer 320 may be in contact with the top surface of the second electrode 330. Alternatively, the electrode 330 may be deposited above the enhancement layer 320. In other words, the enhancement layer 320 could be located between two electrodes, with one of the electrodes being a thin layer of metallic or non-metallic material that is deposited above the enhancement layer 320. The nanoparticles of the outcoupling layer 350 may then be deposited above the second electrode 330. A dielectric spacer layer 340 may be deposited between the second electrode 330 and the nanoparticle layer. The thickness of the dielectric spacer layer 340 may be less than 75 nm, less than 50 nm, more preferably less than 20 nm. In some embodiments, the nanoparticles may be deposited directly above the second electrode 330.

Regardless of the location, the electrode may have a thickness of less than 60 nm. The electrode (which may be the first electrode, second electrode, and/or other electrode) may be made of an optically transparent material, for example, indium tin oxide, fluorine doped tin oxide, indium doped zinc oxide, aluminum zinc oxide, indium-doped cadmium oxide, barium stannate, carbon nanotubes, graphene, multilayer graphene, single layer graphene, graphene oxide, metallic nanoparticles, nanowire impregnated materials, polyacetylene, polypyrrole, polyindole, polyaniline, Poly(p-phenylene vinylene), poly(3-alkylthiophenes), (poly(3,4-ethylenedioxythiophene)), strontium niobium oxide, and/or the like. A thickness of the second, optically transparent, electrode may be less than 60 nm, less than 50 nm, less than 30 nm, less than 20 nm, and/or the like, or, preferably, 20 nm±5 nm. In some embodiments, the second electrode may be disposed over the enhancement layer, with the enhancement layer disposed over the emissive layer. In such an embodiment, the second electrode may be a metal electrode, non-metallic electrode (which may include electrodes having some metallic and some non-metallic material or an electrode with completely non-metallic material), with a thickness of less than 20 nm, less than 30 nm, less than 50 nm, less than 100 nm, and/or the like, or preferably 30 nm±5 nm. The distance between the top of the emissive material layer and the bottom of the electrode may be less than 10 nm, less than 20 nm, less than 30 nm, less than 50 nm, less than 60 nm, less than 100 nm, and/or the like, or, preferably, 20 nm±5 nm. The electrode may also be deposited directly on the top surface of the EML layer.

The outcoupling layer includes arrays of nanoparticles deposited above or below the enhancement layer. The outcoupling layer converts plasmons to light, preferably plasmons in the enhancement layer. The ordering of the nanoparticles in the outcoupling layer may be random or periodic with positional ordering. The nanoparticles in the outcoupling layer act as an optical antenna to outcouple the light. Plasmonic OLEDs with ordered arrays of nanoparticles utilize collective modes within the outcoupling layer to outcouple light, in addition to the antenna mode outcoupling. For the collective outcoupling modes, the electromagnetic field induced in the outcoupling layer, from the plasmonic modes in the enhancement layer, is not localized to a single location, but rather extends over several particles within the periodic array. This collective mode, also referred to as a lattice mode, can enhance light emission at specific angles when the scattering components in plane to the nanoparticle lattice constructively interfere. In some cases, the collective model light emission is leading to directional emission while in other cases when the symmetry is high the emission can be less directional. The emission pattern from a plasmonic OLED utilizing ordered nanoparticle arrays for light outcoupling is the convolution of the structure factor of the nanoparticle arrays and the momentum distribution of the emitter at the outcoupling wavelength. The excited energy from the emitter can be coupled to the arrays by the following pathways given by the momentum matching conditions described below.

$${k}_{0} = \vert {k}_{x} + {G}_{{m}_{1} , {m}_{2}} \vert$$

photon) from the emitter couples directly with the nanoparticle lattice, which may be coupled without passing through any plasmonic mode, resulting in surface lattice resonance (SLR) which enhances the light outcoupling at emission wavelength given by the momentum matching condition:
Where k₀ is the wave vector of the incident light, kₓ=k₀ sin(θ) the wave vector for the in-plane scattering component of the light, where θ is the angle between the incident light and normal to the device surface and Gₘ_{₁}_{,m}_{₂} is the grating vector defined by the Miller m₁, m₂, representing a grating order.

In a second example, the emission from the emitter couples into the surface plasmon mode(s) of the enhancement layer. Photons are created from the surface plasmon modes of the enhancement layer under the following equation:

$${k}_{0} = \vert {k}_{x} + {k}_{spp} + {G}_{{m}_{1} , {m}_{2}} \vert$$

Where Kₛₚₚ is the wave vector associated with the surface plasmon modes. The plasmon-mediated surface lattice resonances (PSLR) will be red-shifted from the SLR modes, due to coupling to the surface plasmon modes.

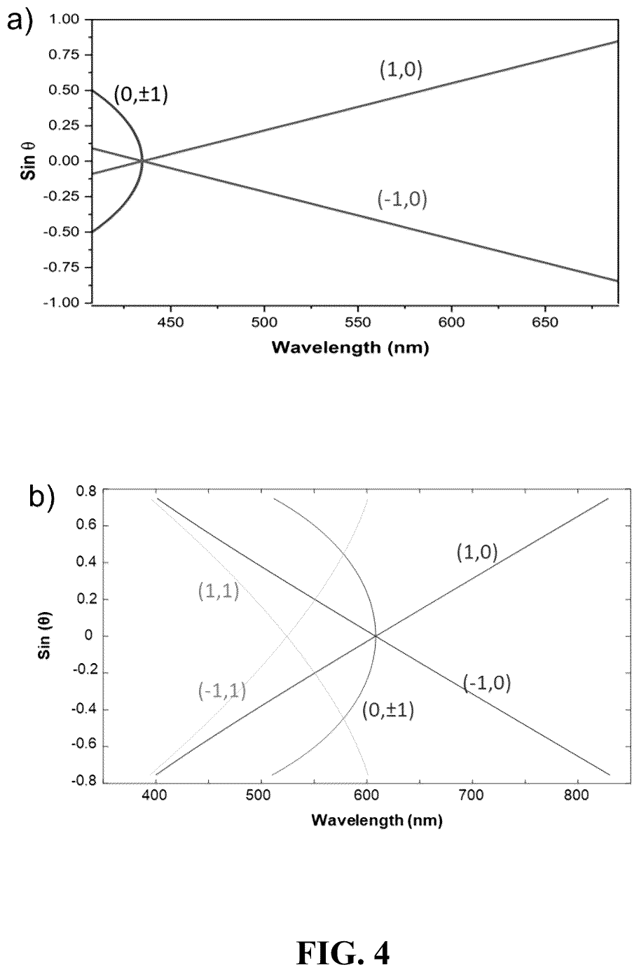

FIG. 4 shows the calculated lattice modes for plasmonic OLED devices using square arrays of silver nanoparticles for light outcoupling using the momentum matching condition described above. The numbers in brackets indicate the Miller indices for different lattice modes. FIGS. 4A and 4B illustrate simulated dispersion mode for the surface lattice resonance (SLR) mode and plasmon-mediated surface lattice resonance (PSLR) mode, respectively. These modes are illustrated for an OLED device using a square array of silver nano cubes with a lattice periodicity of 300 nm for light outcoupling. These dispersion curves indicate the light emission direction from the plasmonic OLEDs. The lattice dispersions for a plasmonic OLED using nanoparticle arrays can be determined by measuring the angle dependent emission spectra or by using spectral Fourier imaging. Additionally, the Fourier plane imaging can provide the wavevector map at any emission wavelength, which indicates the emission pattern for the light emitted from the device. For light emission normal to the device (θ=0, kₓ=0) different lattice modes intersect, which results in enhanced light outcoupling at these wavelength regions. Additionally, the light emission direction from the devices can be tuned by varying the spectral position of the device emission relative to the wavelength region corresponding to kₓ=0. The light outcoupling from the devices using ordered array of nanoparticles are achieved through the antenna modes of individual nano particles and collective modes due to the lattice resonance modes arising from the arrangement of multiple nanoparticles in the array. The light outcoupling due to the antenna modes result in a broader angular emission profile, while the lattice dispersion modes induce directional emission in many cases. The angular emission profile depends on the relative strength of each mode, which can be controlled by varying the spacer layer thickness. For smaller spacer layer thickness (<30 nm) the individual nano antenna modes will be a dominant mode of light outcoupling resulting in a broader emission profile with increased emission intensity at one or more than one emission angles determined by the spectral overlap with the kₓ=0 of the lattice dispersion modes. For higher spacer layer thickness, the light outcoupling by the lattice modes dominates and the light emission can be highly directional. In an embodiment, for spacer layer thickness from 10-25 nm, individual particle outcoupling mode dominates the emission profile. In other words, more than 70% of the light is outcoupled though the individual particle outcoupling when the spacer layer thickness is 10-25 nm. In an embodiment, for spacer layer thicknesses from 26-35 nm, a mixture of the individual particle outcoupling mode and the lattice outcoupling mode are in the emission profile. In other words, individual particle mode outcouples 30-70% of the total outcoupled light, and light outcoupling through the lattice outcoupling mode is 30-70% of the emitted light, where the total outcoupled light through the individual particle and the lattice outcoupling mode is 100%, when the spacer layer thickness is 26-35 nm. In an embodiment, for a spacer layer thickness greater than 36 nm, the lattice outcoupling modes dominate the emission profile. In other words, the light outcoupling through the lattice outcoupling mode is more than 70% of the total outcoupled light when the spacer layer thickness is greater than 36 nm. For thickness less than 10 nm, the light outcoupling mechanism is more complicated, as the individual particle outcoupling becomes less efficient and may be equal/less efficient compared to lattice modes.

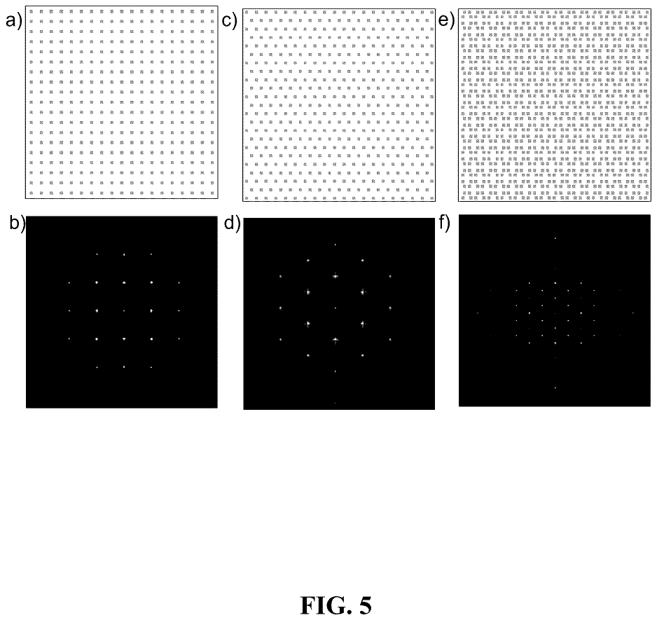

The emission profile of the device can be engineered by modifying the lattice dispersion mode. Specifically, the emission profile of the device can be engineered by arranging the nanoparticles in the outcoupling layer in a specific way. This arrangement is characterized in terms of the array symmetry, which may be rotational symmetry, translational symmetry, and/or the like. By optimizing the array symmetry, the outcoupling efficiency of the device can be increased and the emission profile can be tuned. For example, FIGS. 5a and 5c represent the nanoparticle locations in square and hexagonal lattices, respectively. The array symmetry can be characterized by analyzing the Fourier transform of the particle locations within the array. The bright regions in the Fourier pattern shown in FIGS. 5b and 5d, also called structure factor points, represent the symmetry of nanoparticle arrays. Fourier patterns shown in FIGS. 5b and 5d corresponds to the arrays shown in FIGS. 5a and 5c, respectively, indicating square and hexagonal symmetry pattern. The structure factor points indicate the emission pattern for light emission normal to the device. For off-normal emission, the emission pattern can be determined by converting each structure factor point in the Fourier pattern to a circle with radius defined by the relative spectral position with respect to the wavelength region representing kₓ=0. Square, hexagonal, and honeycomb lattices are considered highly ordered. Highly ordered arrays are arrays where nanoparticles are located at fixed distances from other nanoparticles, referred to as the lattice constant. In other words, from any position within the array, another nanoparticle will be located at a fixed distance in a particular direction from another nanoparticle.

Since the light energy from the plasmonic OLEDs using ordered arrays of nanoparticles is outcoupled through the structure factor points, arrays with more structure factor points or higher symmetry can enable enhanced light outcoupling from plasmonic OLEDs. Arrays having increased symmetry and different short-range and long-range positional order can exhibit Fourier patterns. The symmetry may be rotational symmetry, translational symmetry, and/or the like. These arrays can be classified as quasiperiodic arrays. The quasiperiodic array is an array design that has no long-range positional order and has a length scale of a short-range positional periodicity that is no greater than a plasmon propagation length of the enhancement layer. In other words, a quasiperiodic array is an array having a lack of long-range positional periodicity and has a length scale of the short-range positional order that is comparable to or less than the plasmon propagation length of the enhancement layer. The plasmon propagation length for any plasmonic material is defined as the distance at which the energy within the surface plasmon is decayed to 1/e times the maximum energy. The array is considered quasiperiodic because the distance between adjacent nanoparticles changes or varies at different array locations. In other words, the interparticle spacing between the nearby nanoparticles are not the same at array locations which are separated by a length scale longer than the plasmon propagation length. The emission profile for the device can be tuned based upon selection of the array symmetry of a design of the nanoparticle arrays within the outcoupling layer. In other words, selection of arrays having a higher or lower rotational symmetry can be used to tune the emission profile for the device. It should be noted that an array of nanoparticles includes a plurality of nanoparticles arranged in a design. To minimize the effect of near field coupling between particles within a quasiperiodic array, the minimum interparticle spacing, which is the edge to edge spacing between the two adjacent particles, may be kept to larger than a largest dimension of the nanoparticle. For example, the interparticle spacing may be at least 200 nm, at least 300 nm, at least 400 nm, at least 500 nm, and/or the like.

One technique for generating or forming a quasiperiodic array is by combining two or more fundamental or periodic lattice symmetries into an array. In other words, the quasiperiodic array is generated by embedding a first periodic array within a second periodic array. While two periodic arrays will be discussed herein for ease of readability, it should be noted that more than two periodic arrays can be combined to generate the quasiperiodic array. For example, three, four, five, and/or the like, periodic arrays can be combined to generate the quasiperiodic array. In the embodiment where two periodic arrays are combined or embedded, each of the periodic arrays may have different lattice symmetry and positional order. In other words, the first periodic array would have a first periodic order and the second periodic array would have a second periodic order different from the first periodic order. In the embodiment where more than two periodic arrays are combined or embedded, only a difference of two lattice symmetries or periodicities may be needed among the number of periodic arrays. For example, in the case of three periodic arrays, the first and second periodic arrays may have different lattice symmetries as compared to each other, but the third periodic array could have a lattice symmetry that is the same as either the first or second periodic array. Alternatively, all the periodic arrays may have different lattice symmetries as compared with each other. Different lattice symmetries may include a square lattice, a hexagonal lattice, an oblique lattice, a rectangular lattice, and/or the like. In an embodiment, there may be periodic arrays with the same lattice symmetry, but each lattice may have the same or different periodic spacing.

An example of generation of a quasiperiodic array generated from two periodic arrays is illustrated in FIG. 5e. The corresponding structure factor pattern is shown in FIG. 5f. The quasiperiodic array illustrated in FIG. 5e is generated from a group of nanoparticles forming the square lattice periodic array of FIG. 5a assembled into a hexagonal lattice periodic array of FIG. 5c. In this example, each nanoparticle location of the hexagonal array of FIG. 5c is replaced with four nanoparticles of the square array of FIG. 5a, thereby embedding the square array into the hexagonal array. In other words, the quasiperiodic array of FIG. 5e is formed by a hexagonally ordered unit cell, or grouping, of particles, with each unit cell, or grouping, having four particles arranged in a square lattice. Thus, each of the nanoparticle locations of the hexagonal array is replaced with a grouping of nanoparticles with a square lattice periodicity. The number of nanoparticles in each grouping can be varied to result in more or less complex quasiperiodic arrays. For example, the grouping of nanoparticles from the square array may be an even number, for example, four, six, eight, and/or the like. The lattice periodicity within each unit cell, or grouping, may be at least 100 nm, at least 200 nm, at least 300 nm, at least 400 nm, more than 500 nm, and/or the like. As can be seen in FIG. 5f, the corresponding structure factor pattern illustrates the increased lattice symmetry as compared to the basic periodic arrays of FIG. 5a and FIG. 5c.

It should be noted that reversing which periodic lattice symmetry is embedded within the other periodic lattice symmetry will result in a different quasiperiodic lattice design. In other words, and for example, in the example illustrated in FIG. 5e, the square lattice periodic array of FIG. 5a was embedded in the hexagonal lattice periodic array of FIG. 5c. In other words, for each point in the hexagonal lattice periodic array, the square lattice periodic array was positioned. However, if the hexagonal lattice periodic array of FIG. 5c is embedded in the square lattice periodic array of FIG. 5a, in other words, for each point in the square lattice periodic array, the hexagonal lattice periodic array was positioned, the resulting quasiperiodic array design would be different than that illustrated in FIG. 5e. In some embodiments the quasiperiodic arrays may be prepared by introducing chirping to the basic arrays. Chirping refers to gradual and systematic change in lattice properties across the nano particle array. The positional chirping involves gradual changes in the lattice periodicity or interparticle spacing along one or more than one ordering direction in a nano particle array. Chirping can be done in array symmetry as well, where the lattice symmetry may be gradually changed from one symmetry to another for example from hexagonal to rectangular array symmetry. In some embodiments the changes in lattice periodicity for example from periodicity 1 to periodicity 2 may be applied within 10 lattice periods, 20 lattice periods, 50 lattice periods or more than 100 lattice periods. The chirping of arrays results in a broadening of lattice dispersion modes, including the kₓ=0 regions, which can broaden the light outcoupling due to the lattice modes. The array chirping may be beneficial to increase the light outcoupling efficiency from devices using spectrally broader emitter by maximizing the spectral overlap with the lattice modes.

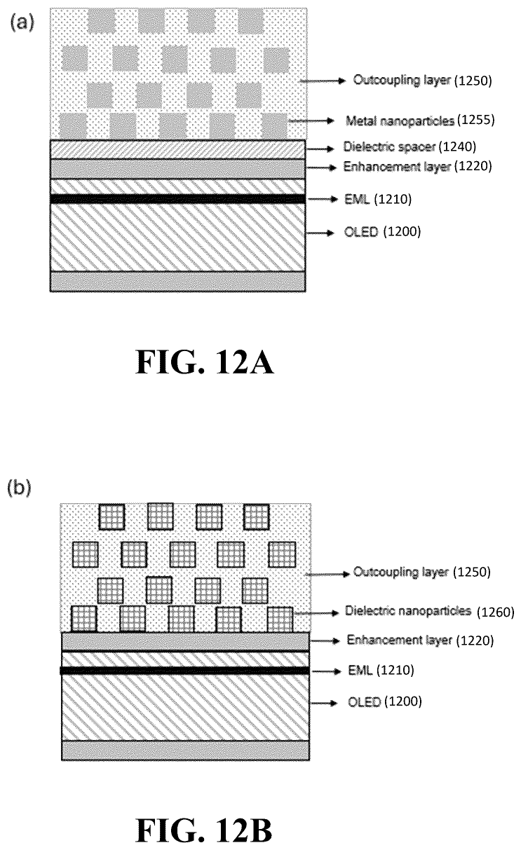

In some embodiments, the quasi-periodic array may be a higher order array as compared to the arrays that are generated from embedding one periodic array within another. One technique for generating these higher order arrays is to utilize a cut and project method. A cut and project method is a mathematical technique where a higher dimensional lattice is projected into a two-dimensional plane to create a tiling pattern. Once the tiling pattern is generated, nanoparticles can be positioned at points defined by the vertices of the tiling pattern to generate quasiperiodic arrays. For example, a five-dimensional cubic lattice may be formed by cubes that are stacked. This five-dimensional lattice is then projected into a two-dimensional plane to create the Penrose tiling pattern. By increasing the dimensionality of the lattice to be projected, the array symmetry of the projected arrays increases. The increase in symmetry point of the arrays, which is a point in the Fourier pattern or inverse space, also called structure factor points, increases the outcoupling efficiency of the device. Owing to the increased rotational and translational symmetry, the quasiperiodic arrays may exhibit multiple dispersion modes. In some embodiments, where the variation in interparticle spacing is gradual, example chirped arrays the quasiperiodic arrays may exhibit broader lattice dispersion mode, broadening the light outcoupling due to the lattice modes. This can result in broadening of angular emission profile as the array modes which are not in resonance with the emission peak promotes light emission at off normal angles. In some embodiments, the angular emission profile due to the quasiperiodic arrays may be broader than the Lambertian profile. In some other embodiments where the quasiperiodic arrays have multiple discrete interparticle spacing, multiple sharp lattice dispersion modes may be observed. Each of these dispersion modes can induce light emission in specific emission directions depending on the spectral overlap with the emission spectra. The angular emission profile for these devices may show multiple emission directions due to the lattice modes along with the border emission profile due to the individual nano antenna outcoupling mode. FIG. 11A-11C show nanoparticle locations and arrangements. FIG. 11A illustrates a hexagonal array. FIG. 11B shows a chirped array showing variations in lattice periodicity. FIG. 11C shows a chirped array showing variation in array symmetry from hexagonal to rectangular. FIGS. 12A and 12B show 3-dimensional nanoparticle locations and arrangements. FIG. 12A illustrates 3-dimensional metal nanoparticles 1255. FIG. 12B illustrates 3-dimensional dielectric nanoparticles 1260. In some embodiments the nanoparticles in the outcoupling layer 1250 may form 3-dimensional lattice exhibiting positional ordering and array symmetry in the out-of-plane (i.e. perpendicular to the enhancement layer 1220) direction. In an embodiment, as shown in FIGS. 12A and 12B, at least a portion of the nanoparticles may be surrounded by another layer (i.e. the spacer layer or dielectric layer 1240). In an embodiment, when dielectric nanoparticles are used, the another layer surrounding the nanoparticles may have a refractive index selected from the group consisting of: less than 2.5, less than 2.0, less than 1.9, less than 1.8, less than 1.7, less than 1.6, and less than 1.5. The nanoparticle array symmetry may include but are not limited to cubic, orthorhombic, trigonal, tetragonal, hexagonal, triclinic, monoclinic, body centered cubic, face centered cubic, etc.

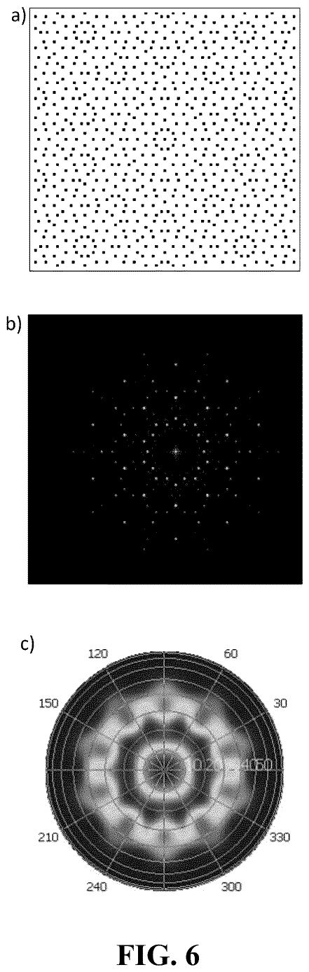

One example of a higher order array is a quasiperiodic array having a Penrose design. Such a quasiperiodic array having a Penrose design is illustrated in FIG. 6a. This quasiperiodic array was generated from a Penrose tiling pattern formed by the projection of a five-dimensional cubic lattice to a two-dimensional plane. FIG. 6b illustrates the Fourier pattern representing geometrical structure factor points generated from the quasiperiodic array of FIG. 6a. FIG. 6b shows the increase in structure factor points for the arrays prepared from the Penrose tiling pattern. This increase is due to the local and long-range positional order with the five-fold rotational symmetry of the Penrose tiling pattern and further illustrating the reduced positional periodicity. The simulated emission profile at 625 nm using the Penrose quasiperiodic array of FIG. 6a is depicted in FIG. 6c. This simulated emission profile shows excellent agreement with the geometrical structure factor points shown in FIG. 6b.

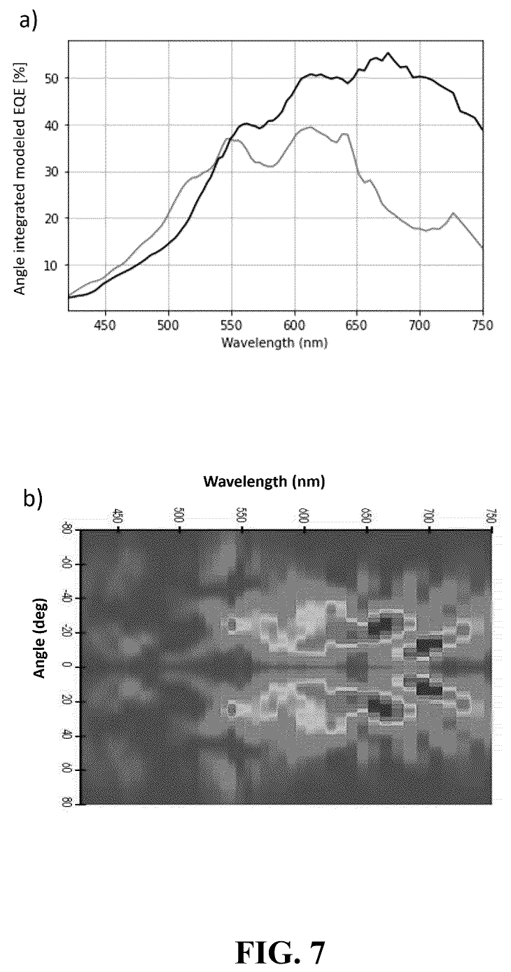

FIG. 7a shows the estimated EQE variation for a plasmonic OLED using Penrose-based quasiperiodic arrays for light outcoupling, which shows enhanced light outcoupling as compared to a device utilizing square arrays of particles for light outcoupling. FIG. 7b illustrates the EQE plot for the Penrose-based quasiperiodic array that shows a broad peak that is due to the modified lattice dispersion as shown in FIG. 7b. The simulations were performed using a finite difference time domain (FDTD) method using Ansys® Lumerical FDTD solutions. ANSYS is a registered trademark of Ansys, Inc. in the United States and other countries. Different layers of the OLED devices were rendered into a computational volume of 7 μm×7 μm×1.5 μm by their refractive index values and were enclosed within the perfectly matched layer (PML) in all directions to match the open boundary conditions. A single dipole emitter in vertical or horizontal orientation with a broad emission spectrum covering the entire visible region (420 nm-750 nm), placed 20 nm away from a 30 nm thick silver electrode acting as the emissive layer. A 75 nm thick non-absorbing dielectric layer with a refractive index of 1.7 to model the host medium was used. The metallic and dielectric structures of the outcoupling layer with optimum dimensions and ordering were placed above the cathode. Experimentally determined refractive index values to model the silver cathode and the refractive values by Johnson and Christy were used for modeling metallic structures (nanoparticles) in the outcoupling layer. The computational volume was discretized with a non-uniform index adjusted rectangular mesh with a resolution of 34 mesh cells per wavelength. Additionally, a mesh override region with 2 nm resolution was applied in the simulation region encompassing the silver cathode and metallic structures to minimize the computational error. The Purcell enhancement was estimated by calculating the power emitter by the dipole using a box of monitors surrounding the emitter normalized to the free space emission power. The light emissions in the far field were recorded using a frequency-domain field and power monitor placed 500 nm above the outcoupling layer, which were used to estimate the external quantum efficiency (EQE) of the device. The monitor also records the electric and magnetic field components induced by the dipole emitter.

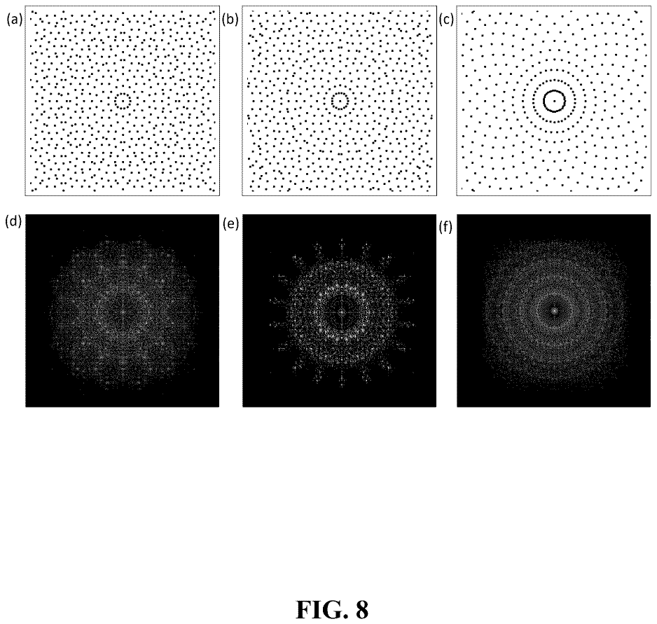

As previously mentioned, arrays with higher orders can be formed by increasing the dimensionality of the higher dimensional lattice to be projected. For example, using the example of the cubic lattice, increasing the dimensionality of the cubic lattice from five to six, seven, eight, and/or the like, increases the order of the resulting quasiperiodic array. This increase in the dimensionality increases the symmetry of the quasiperiodic array. The increase in the order of the resulting quasiperiodic array increases the number of structure factor points, which can result in enhanced light outcoupling. FIG. 8 illustrates the quasiperiodic arrays that result from an increase in the dimensionality of the higher dimensional cubic lattices. FIG. 8A illustrates the quasiperiodic high symmetry array from a tiling pattern where the dimensionality of the cubic lattice is equal to 7. FIG. 8D illustrates the corresponding structure factor pattern for the array of FIG. 8A. FIG. 8B illustrates the quasiperiodic high symmetry array from a tiling pattern where the dimensionality of the cubic lattice is equal to 9. FIG. 8E illustrates the corresponding Fourier pattern representing structure factor points for the array of FIG. 8B. FIG. 8C illustrates the quasiperiodic high symmetry array from a tiling pattern where the dimensionality of the cubic lattice is equal to 13. FIG. 8F illustrates the corresponding Fourier pattern representing structure factor points for the array of FIG. 8C. It should be noted that the broader range of interparticle spacing with the increase in the array symmetry can affect the outcoupling efficiency, particularly when the edge-to-edge spacing between adjacent nanoparticles is less than the size of the nanoparticles. This nearfield coupling between the nanoparticles can reduce the outcoupling efficiency. Accordingly, to reduce these effects, the nanoparticle ordering can be modified locally at array locations where the edge-to-edge spacing between adjacent nanoparticles is comparable to or less than the nanoparticle size with minimal changes in the lattice symmetry.

The modification of the geometrical structure factor points, by using quasiperiodic arrays provides an efficient way to tune the emission pattern from the plasmonic OLED, which also enhances the light outcoupling. Metal nanoparticles used in the outcoupling layer may have a shape, for example, cubes, spheres, hemispheres, cylinders, rectangles, and/or the like. In an embodiment, the metal nanoparticles may have a maximum cross-sectional size within the shape between 5 nm and 1000 nm. In an embodiment, if the metal nanoparticles 1060 are a cube or rectangular prism, the maximum length of a single edge of the cube or rectangular prism is between 5 nm, and 1000 nm. The smallest in-plane particle dimension of the metal nanoparticles may be greater than 10 nm, greater than 50 nm, greater than 100 nm, greater than 200 nm, greater than 300 nm, greater than 500 nm, greater than 1000 nm, greater than 1500 nm, greater than 2000 nm, and/or the like. The out-of-plane dimension of the metal nanoparticles may be greater than 10 nm, greater than 50 nm, greater than 100 nm, greater than 200 nm, greater than 300 nm, greater than 500 nm, greater than 1000 nm, greater than 1500 nm, greater than 2000 nm, and/or the like. The outcoupling layer may also include a dielectric spacer having a thickness of less than 20 nm, less than 30 nm, less than 50 nm, less than 100 nm, and/or the like, or, preferably, 20 nm±5 nm. The dielectric spacer may be disposed above the enhancement layer and the arrays of nanoparticles may be disposed above the dielectric spacer. The refractive index of the dielectric spacer can be less than 1.5, less than 2, less than 2.5, and/or the like.

In some embodiments, the quasiperiodic arrays may include dielectric nanoparticles, either in addition to or instead of the metal nanoparticles, meaning the outcoupling layer may include dielectric nanoparticles, metal nanoparticles, and/or a combination of both. Dielectric nanoparticles used in the outcoupling layer may have a shape, for example, cylinders, cubes, hemispheres, cones, truncated cones, any random shape having a flat face, and/or the like. The refractive index of the dielectric material can be at least 1.5, at least 2, at least 2.5, at least 3, and/or the like, or, preferable 2.4±0.2. In some embodiments, the quasiperiodic arrays will be disposed directly on the enhancement layer. In other embodiments, the outcoupling layer may include a dielectric spacer having a thickness of less than 10 nm, which will be located between the enhancement layer and the nanoparticle layer. In some embodiments, no dielectric spacer may be included.

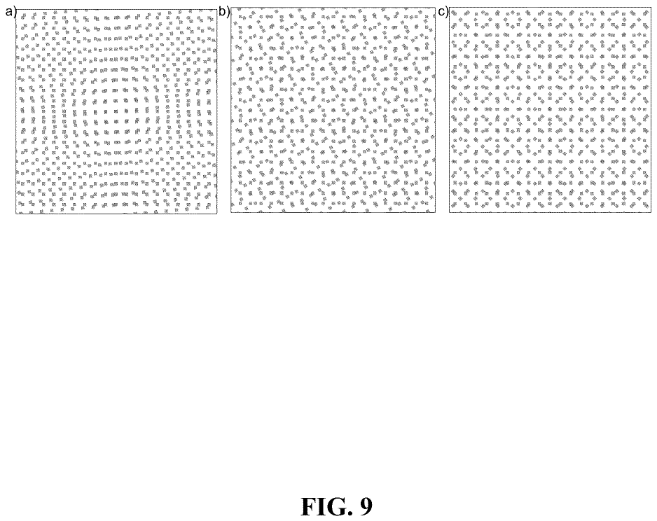

In some embodiments, the nanoparticles of the outcoupling layer will be arranged in a Moiré pattern to control the emission pattern and the emission direction for the plasmonic OLED. The Moiré patterns can be formed by layering multiple periodic arrays. For example, the quasiperiodic array may be generated by layering a first periodic array with a second periodic array, where the resulting quasiperiodic array exhibits a Moiré effect. The periodic arrays are rotated with respect to each other in generating the quasiperiodic array. In other words, the quasiperiodic arrays exhibiting a Moiré effect can be formed by superimposing multiple periodic nanoparticle arrays that are twisted with respect to each other. Thus, the periodic array symmetries can be the same or different. For example, the arrays utilized to generate the quasiperiodic array may be all square arrays, all hexagonal arrays, different array types, and/or the like. The degree of rotation between the arrays may be 1-15°, 16-30°, 31-45°, and/or the like. FIG. 9 represents a quasiperiodic array exhibiting a Moiré effect formed using two square arrays of equal periodicity. In FIG. 9a, the quasiperiodic array is formed with the square arrays being rotated with respect to each other by 5°. In FIG. 9b, the quasiperiodic array is formed with the square arrays being rotated with respect to each other by 30°. In FIG. 9c, the quasiperiodic array is formed with the square arrays being rotated with respect to each other by 45°. The degree of rotation may be selected to tune a radiation pattern and emission direction of the device. In other words, the low spatial frequency Moiré pattern formed by the superposition of multiple high spatial frequency array patterns enables the tuning of the radiation pattern and emission direction from the plasmonic OLED by controlling the twist angle between the arrays. Additionally, the Moiré effect modifies the lattice dispersion, resulting in a flatter dispersion, which reduces the angle dependent color shift for the plasmonic OLED.

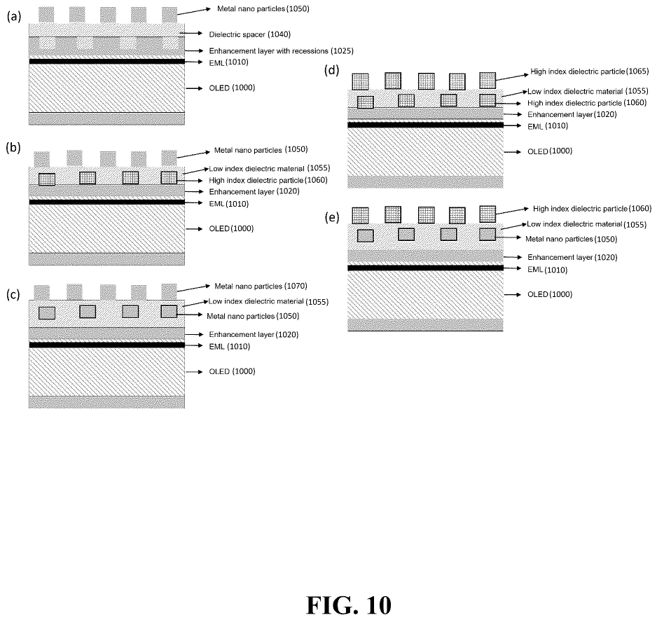

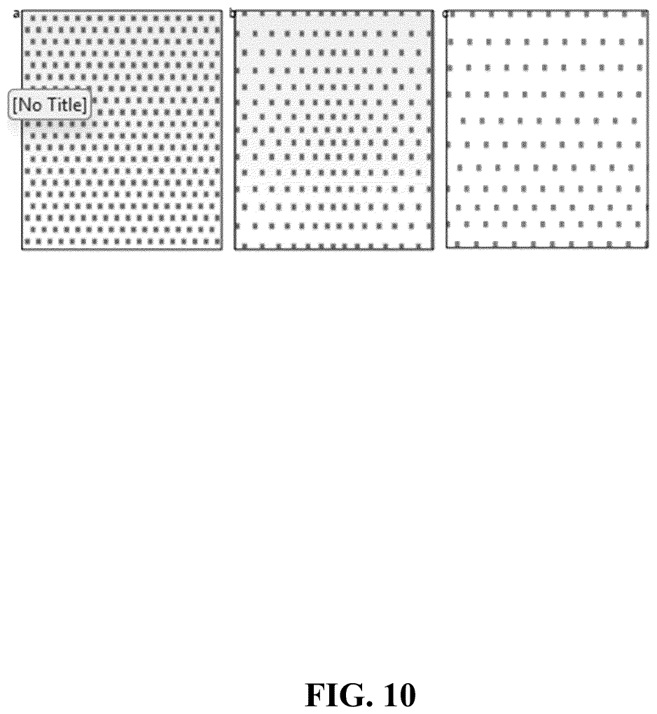

In some embodiments, the nanoparticles of the first periodic array and the nanoparticles of the second periodic array are arranged within the same plane, thereby creating a quasiperiodic Moiré array. In this embodiment, the nanoparticles of the first periodic array and the nanoparticles of the second periodic array have the same type. In other words, in this quasiperiodic array, the nanoparticles are either all metal nanoparticles or all dielectric nanoparticles. In an embodiment, the nanoparticles of the Moiré quasiperiodic array will be fabricated in a dielectric spacer layer of the outcoupling layer and disposed above the enhancement layer. In some embodiments, the nanoparticles will be fabricated directly above the enhancement layer. In some embodiments and as illustrated in FIG. 10a, the Moiré pattern will be formed by an array of recessions in the enhancement layer 1025 that is disposed above the emissive layer 1010 which is disposed above the organic layer 1000. The recessions will be filled with dielectric material 1040, planarizing the top surface. The nanoparticle layer 1050 will be disposed above this planarized top surface. The depth of the recessions may be at least 10 nm, at least 25 nm, less than 50 nm, and/or the like. The refractive index of the dielectric material may be at least 1.5, at least 1.75, greater than 2, and/or the like.

In some embodiments, the periodic arrays will be layered to form a quasiperiodic array exhibiting the Moiré effect. In other words, a first periodic array will be a first layer, and a second periodic array will be a second layer. Since the periodic arrays will remain layered, the nanoparticles of the quasiperiodic array can be different between the layers. For example, the first layer may be dielectric nanoparticles or metal nanoparticles. The second layer may then be dielectric nanoparticles or metal nanoparticles, regardless of which nanoparticle type is used in the first layer. Thus, the combination of layers may be, metal nanoparticles/metal nanoparticles, metal nanoparticles/dielectric nanoparticles, dielectric nanoparticles/dielectric nanoparticles, and dielectric nanoparticles 1060/metal nanoparticles 1050 (illustrated in FIG. 10b). In an embodiment where the first (or bottom) layer is dielectric nanoparticles, the outcoupling layer may include a dielectric spacer having a thickness of less than 2 nm, where the dielectric nanoparticles are disposed over the dielectric spacer. In an embodiment, the dielectric nanoparticles may be disposed directly on the enhancement layer.

In an embodiment, as illustrated in FIG. 10b, dielectric nanoparticles 1060 forming the first (or bottom) layer may be embedded within a dielectric material 1055. The refractive index of the dielectric material may be less than 2, less than 1.8, less than 1.6, and/or the like, or, preferably, less than 1.4. The refractive index of the dielectric particles may be at least 1.5, at least 2, at least 2.5, greater than 3, and/or the like. The difference between the refractive index of the dielectric material and the refractive index of the dielectric particles may be at least 0.5. In other words, the refractive index of the dielectric particles is greater than the refractive index of the dielectric material by at least 0.5. In an embodiment, the dielectric nanoparticles 1060 may have a maximum cross-sectional size within the shape between 5 nm and 1000 nm. In an embodiment, if the dielectric nanoparticles 1060 are a cube or rectangular prism, the maximum length of a single edge of the cube or rectangular prism is between 5 nm and 1000 nm. In an embodiment, the dielectric nanoparticles may have a largest in-plane dimension of greater than 10 nm, greater than 50 nm, greater than 100 nm, greater than 200 nm, greater than 300 nm, greater than 500 nm, greater than 1000 nm, greater than 1500 nm, greater than 2000 nm, and/or the like. In an embodiment, the maximum out-of-plane dimension of the dielectric nanoparticles may be greater than 10 nm, greater than 50 nm, greater than 100 nm, greater than 200 nm, greater than 300 nm, greater than 500 nm, greater than 1000 nm, greater than 1500 nm, greater than 2000 nm, and/or the like. The thickness of the dielectric layer that includes the dielectric nanoparticles may be at least equal to the out-of-plane dimension of the dielectric nanoparticle or may be greater than the out-of-plane dimension of the dielectric nanoparticles to form a planarized surface. The second nanoparticle layer 1050 may then be disposed on the planarized surface. The interparticle spacing between the particles in the arrays may be at least 200 nm, at least 300 nm, at least 400 nm, greater than 500 nm, and/or the like.

FIG. 10c illustrates an embodiment where the first layer 1050 and the second layer 1070 both contain metal nanoparticles. The outcoupling layer may include a dielectric spacer and the first nanoparticle layer 1050 may be deposited above the dielectric spacer. A dielectric material 1055 may be deposited in the regions between the nanoparticles of the first layer 1050 to create a planarized surface. The dielectric material 1055 may have a refractive index of less than 1.5, less than 1.75, less than 2.0, and/or the like. The second nanoparticle layer 1070 may be deposited above the first layer 1050, for example, on the planarized surface. The first and second nanoparticle layers 1050/1070 may be separated by dielectric material having a thickness of less than 100 nm, less than 50 nm, less than 20 nm, and/or the like.

FIG. 10d illustrates an embodiment where the first nanoparticle layer 1060 and the second nanoparticle layer 1065 both contain dielectric nanoparticles. In such an embodiment, the first layer 1060 may be deposited directly above the top surface of the enhancement layer 1020, with a dielectric material 1055 filling the space between the dielectric nanoparticles. In some embodiments, the outcoupling layer may include a very thin dielectric spacer, for example, less than 2 nm, and the first dielectric nanoparticle layer 1060 will be disposed above this dielectric spacer. FIG. 10e illustrates an embodiment where the first nanoparticle layer 1050 includes metal nanoparticles and the second nanoparticle layer 1060 includes dielectric nanoparticles. In such an embodiment, the metal nanoparticle layer 1050 may be deposited above the dielectric spacer layer, for example, as discussed in connection with FIG. 10c. Dielectric material 1055 may be deposited in the regions between the metal nanoparticles 1050 and to form a planarized top surface. Characteristics of the dielectric material may be similar to that described in connection with FIG. 10c. The dielectric nanoparticle layer 1060 may be deposited on the top of the planarized surface.

A quasiperiodic array having a Moiré effect may also be formed by superposing more than two nanoparticle arrays of different periodicities. The example described will refer to three nanoparticle arrays for ease of readability. However, more than three nanoparticle arrays may be utilized. The arrays will be layered to form a stack in the out-of-plane direction. The nanoparticle arrays can be stacked using any of the previously described techniques to create nanoparticle layers that are stacked on top of each other. For example, the first nanoparticle layer may include nanoparticles that are embedded in a medium to create a planar surface. The second nanoparticle layer may be deposited directly above the first nanoparticle layer. A planar surface will be created on the second nanoparticle layer. The third nanoparticle layer may be deposited directly above the second nanoparticle layer. A planar surface will be created on the third nanoparticle layer. This process can continue until the desired number of nanoparticle layers are included in the stack. In some embodiments, each array may be separated in the out-of-plane direction by a distance of at least 10 nm, at least 25 nm, at least 50 nm, and/or the like, or, preferably less than 100 nm.

The angular emission profile due to the Moiré arrays may exhibit emission characteristics similar to the quasiperiodic arrays. In some embodiments the emission profile may be broader than the Lambertian profile, while in some other embodiments the device using Moiré arrays can exhibit multiple emission directions.

It is understood that the various embodiments described herein are by way of example only, and are not intended to limit the scope of the invention. For example, many of the materials and structures described herein may be substituted with other materials and structures without deviating from the spirit of the invention. The present invention as claimed may therefore include variations from the particular examples and preferred embodiments described herein, as will be apparent to one of skill in the art. It is understood that various theories as to why the invention works are not intended to be limiting.

1. A device, the device comprising:
a substrate;
a first electrode;
an emissive layer comprising an organic emissive material disposed over the first electrode;
an enhancement layer disposed over the emissive layer; and
an outcoupling layer disposed over the enhancement layer, wherein the outcoupling layer comprises an array of nanoparticles, wherein the array comprises a periodic array or a quasiperiodic array.

2. The device of claim 1, wherein the emission profile for the device is tuned based upon selection of an array symmetry of a design of the plurality of arrays.

3. The device of claim 2, wherein the array symmetry is selected from the group consisting of at least one of: translational symmetry and rotational symmetry.

4. (canceled)

5. The device of claim 1, wherein the quasiperiodic array comprises an array design having no long-range positional order and wherein a length scale of a short-range positional periodicity is no greater than a plasmon propagation length of the enhancement layer.

6. The device of claim 1, wherein the quasiperiodic array is generated by combining lattice periodicities of a first periodic array within a second periodic array.

7. The device of claim 6, wherein a lattice periodicity within the quasiperiodic array is selected from the group consisting of: at least 100 nm, at least 200 nm, at least 300 nm, at least 400 nm, and more than 500 nm.

8. The device of claim 6, wherein the first periodic array and the second periodic array comprise different lattice periodicities.

9. The device of claim 8, wherein the lattice periodicities are selected from the group consisting of: a square lattice, a hexagonal lattice, an oblique lattice, and a rectangular lattice.

10-15. (canceled)

16. The device of claim 1, wherein an interparticle spacing between nanoparticles within the quasiperiodic array is greater than a largest dimension of a nanoparticle.

17. The device of claim 16, wherein the interparticle spacing is selected from the group consisting of: at least 200 nm, at least 300 nm, at least 400 nm, and at least 500 nm.

18-23. (canceled)

24. The device of claim 1, wherein the quasiperiodic array is generated by layering a first periodic array with a second periodic array.

25. (canceled)

26. The device of claim 24, wherein at least one of the first periodic array and the second periodic array are rotated with respect to each other, wherein a degree of rotation between the first periodic array and the second periodic array is a degree of rotation selected from the group consisting of: 5°, 30°, and 45°.

27-28. (canceled)

29. The device of claim 26, wherein the first periodic array and the second periodic array are arranged within a same plane creating a Moiré array.

30. The device of claim 29, wherein the nanoparticles comprise a nanoparticle type selected from the group consisting of: metal nanoparticles and dielectric nanoparticles.

31-55. (canceled)

56. The device of claim 24, wherein the quasiperiodic array is formed by layering at least a third periodic array with the first periodic array and the second periodic array in a stack in an out-of-plane direction.

57-70. (canceled)

71. The device of claim 1, wherein the enhancement layer comprises a plasmonic material exhibiting surface plasmon resonance that non-radiatively couples to the organic emissive material and transfers excited state energy from the organic emissive material to non-radiative mode of surface plasmon polaritons, wherein the enhancement layer is provided no more than a threshold distance away from the organic emissive material.

72. The device of claim 71, wherein the organic emissive material has a total non-radiative decay rate constant and a total radiative decay rate constant due to the presence of the enhancement layer, and the threshold distance is where the total non-radiative decay rate constant is equal to the total radiative decay rate constant.

73. The device of claim 71, wherein the organic emissive material has a total non-radiative decay rate constant
$${k}_{non - rad}^{0} ,$$
a total radiative decay rate constant
$${k}_{rad}^{0} ,$$
a total non-radiative decay rate constant due to the enhancement layer
$${k}_{non - rad}^{p l a smon} ,$$
and a total radiative decay rate constant due to the enhancement layer
$${k}_{rad}^{plasmon} ;$$
and
wherein the threshold distance is a distance at which
$$\frac{{k}_{rad}^{plasmon}}{{k}_{non - rad}^{plasmon}} = \frac{{k}_{rad}^{0}}{{k}_{non - rad}^{0}} .$$

74. A consumer electronic device comprising:
a substrate;
a first electrode;
an emissive layer comprising an organic emissive material disposed over the first electrode;
a second electrode disposed over the emissive layer; and
an outcoupling layer disposed over the enhancement layer, wherein the outcoupling layer comprises an array of nanoparticles, wherein the array comprises a periodic array or a quasiperiodic array.

75. The consumer electronic device of claim 74, wherein the device is at least one type selected from the group consisting of: a flat panel display, a curved display, a computer monitor, a medical monitor, a television, a billboard, a light for interior or exterior illumination and/or signaling, a heads-up display, a fully or partially transparent display, a flexible display, a rollable display, a foldable display, a stretchable display, a laser printer, a telephone, a cell phone, tablet, a phablet, a personal digital assistant (PDA), a wearable device, a laptop computer, a digital camera, a camcorder, a viewfinder, a micro-display that is less than 2 inches diagonal, a 3-D display, a virtual reality or augmented reality display, a vehicle, an automotive display, a video walls comprising multiple displays tiled together, a theater or stadium screen, and a sign.
